(19) United States
(12) Patent Application Publication
(10) Pub. No.: US 2025/0380602 A1
(43) Pub. Date: Dec. 11, 2025

(54) DISPLAY APPARATUS

(71) Applicant: Samsung Display Co., Ltd., Yongin-si (KR)

(72) Inventors: Kwangsoo Bae, Yongin-si (KR); Gunhee Kim, Yongin-si (KR); Yongjo Kim, Yongin-si (KR); Bokwang Song, Yongin-si (KR); Sooyeong Hong, Yongin-si (KR)

(21) Appl. No.: 19/230,767

(22) Filed: Jun. 6, 2025

(30) Foreign Application Priority Data
Jun. 10, 2024 (KR) 10-2024-0075286

(51) Int. Cl. H10K 59/80; H10K 39/34; H10K 59/38

(52) U.S. Cl. CPC H10K 59/8792; H10K 39/34; H10K 59/38

(57) ABSTRACT

A display apparatus includes a substrate, a light-emitting device and an auxiliary light-emitting device on the substrate, a light-receiving device on the substrate and including a first light-receiving device and a second light-receiving device, the first light-receiving device being configured to absorb light in a visible light wavelength band and the second light-receiving device being configured to absorb light in an infrared wavelength band, and a wavelength conversion pattern on the light-emitting device, the auxiliary light-emitting device, and the light-receiving device, wherein the wavelength conversion pattern includes an infrared quantum dot material configured to convert light in the visible light wavelength band into light in the infrared wavelength band.

### CROSS-REFERENCE TO RELATED APPLICATION

The present application claims priority to and the benefit of Korean Patent Application No. 10-2024-0075286, filed on Jun. 10, 2024, in the Korean Intellectual Property Office, the entire disclosure of which is incorporated herein by reference.

### BACKGROUND

### 1. Field

Aspects of one or more embodiments relate to the structure of a display apparatus.

### 2. Description of the Related Art

In general, a display apparatus includes a light-emitting device, such as an organic light-emitting diode, and a thin-film transistor on a substrate and operates by causing light-emitting devices to emit light.

For example, each pixel of the display apparatus has a light-emitting device, such as an organic light-emitting diode, in which an intermediate layer including an emission layer is arranged between a pixel electrode and a counter electrode. In the display apparatus, whether or not to emit light or the degree of light emission of each pixel may generally be controlled through the thin-film transistor electrically connected to the pixel electrode. Some layers included in the intermediate layer of the light-emitting device may be commonly provided for a plurality of light-emitting devices.

The above information disclosed in this Background section is only for enhancement of understanding of the background and therefore the information discussed in this Background section does not necessarily constitute prior art.

### SUMMARY

Aspects of some embodiments include a display apparatus in which complex sensing, such as fingerprint sensing, biometric information sensing, and touch sensing, may be performed. However, the disclosed embodiments are only examples, and the scope of embodiments according to the present disclosure are not limited thereto.

Additional aspects will be set forth in part in the description which follows and, in part, will be apparent from the description, or may be learned by practice of the presented embodiments of the disclosure.

According to some embodiments, a display apparatus includes a substrate, a light-emitting device on the substrate and including a first light-emitting device, a second light-emitting device, and a third light-emitting device, the first to third light-emitting devices being configured to emit light of different colors from each other, an auxiliary light-emitting device on the substrate and apart from the light-emitting device, a light-receiving device on the substrate and including a first light-receiving device and a second light-receiving device, the first light-receiving device being configured to absorb light in a visible light wavelength band, and the second light-receiving device being configured to absorb light in an infrared wavelength band, a thin-film encapsulation layer on the light-emitting device, the auxiliary light-emitting device, and the light-receiving device, a light-blocking layer on the thin-film encapsulation layer and including a plurality of openings respectively corresponding to the light-emitting device, the auxiliary light-emitting device, and the light-receiving device, and a wavelength conversion pattern on the light-blocking layer, wherein the wavelength conversion pattern includes an infrared quantum dot material configured to convert light in the visible light wavelength band into light in the infrared wavelength band.

According to some embodiments, an emission layer included in the auxiliary light-emitting device may be configured to emit light of a same color as that of light emitted from one of the first light-emitting device, the second light-emitting device, and the third light-emitting device.

According to some embodiments, the first light-emitting device may be further configured to emit light in a wavelength band of about 495 nm to about 580 nm, the second light-emitting device may be further configured to emit light in a wavelength band of about 380 nm to about 495 nm, and the third light-emitting device may be further configured to emit light in a wavelength band of about 580 nm to about 780 nm.

According to some embodiments, the emission layer included in the auxiliary light-emitting device may be further configured to emit light in a wavelength band of about 380 nm to about 495 nm.

According to some embodiments, the first light-receiving device may be further configured to absorb light in a wavelength band of about 380 nm to about 780 nm, and the second light-receiving device may be further configured to absorb light in a wavelength band of about 750 nm to about 1,500 nm.

According to some embodiments, in a plan view, an emission area of the auxiliary light-emitting device may be smaller than an emission area of each of the first light-emitting device, the second light-emitting device, and the third light-emitting device.

According to some embodiments, the auxiliary light-emitting device and the second light-receiving device may be arranged adjacent to each other.

According to some embodiments, in a plan view, the auxiliary light-emitting device may be arranged between two second light-emitting devices arranged adjacent to each other.

According to some embodiments, in a plan view, the second light-receiving device may be arranged between the second light-emitting device and the auxiliary light-emitting device.

According to some embodiments, in a plan view, the second light-receiving device may be arranged between two auxiliary light-emitting devices arranged adjacent to each other.

According to some embodiments, the display apparatus may further include a color filter layer on the light-blocking layer and the wavelength conversion pattern, wherein the color filter layer may include a first color filter corresponding to the first light-emitting device, a second color filter corresponding to the second light-emitting device, and a third color filter corresponding to the third light-emitting device.

According to some embodiments, the display apparatus may further include a transparent organic film layer arranged in an opening corresponding to the second light-receiving device, among the plurality of openings of the light-blocking layer.

According to some embodiments, the display apparatus may further include a first sensing color filter arranged in an opening corresponding to the first light-receiving device, among the plurality of openings of the light-blocking layer, and a second sensing color filter arranged in an opening corresponding to the second light-receiving device, among the plurality of openings of the light-blocking layer.

According to some embodiments, the first sensing color filter may include a same material as that of the first color filter corresponding to the first light-emitting device, the first light-emitting device being further configured to emit green light. According to some embodiments, the second sensing color filter may include

a same material as that of the third color filter corresponding to the third light-emitting device, the third light-emitting device being further configured to emit red light.

According to some embodiments, the wavelength conversion pattern may be arranged in an opening corresponding to the auxiliary light-emitting device, among the plurality of openings of the light-blocking layer.

According to some embodiments, the display apparatus may further include an auxiliary color filter on the wavelength conversion pattern, wherein the auxiliary color filter may include a same material as that of the third color filter corresponding to the third light-emitting device, the third light-emitting device being further configured to emit red light.

According to some embodiments, the wavelength conversion pattern may be on an upper surface of the light-blocking layer.

According to some embodiments, the display apparatus may further include a fourth color filter arranged in an opening corresponding to the auxiliary light-emitting device, among the plurality of openings of the light-blocking layer, wherein the fourth color filter may include a same material as that of the second color filter corresponding to the second light-emitting device, the second light-emitting device being further configured to emit blue light.

According to some embodiments, the display apparatus may further include an auxiliary color filter on the fourth color filter, wherein the auxiliary color filter may include a same material as that of the third color filter corresponding to the third light-emitting device, the third light-emitting device being further configured to emit red light.

According to some embodiments, the wavelength conversion pattern may be on the light-blocking layer surrounding an opening corresponding to the auxiliary light-emitting device, among the plurality of openings of the light-blocking layer.

According to some embodiments, the wavelength conversion pattern may be on the light-blocking layer surrounding an opening corresponding to the second light-receiving device, among the plurality of openings of the light-blocking layer.

### BRIEF DESCRIPTION OF THE DRAWINGS

The above and other aspects, features, and characteristics of certain embodiments of the disclosure will be more apparent from the following description taken in conjunction with the accompanying drawings, in which:

FIG. 1 is a schematic plan view of a portion of a display apparatus according to some embodiments;

FIG. 2 is a schematic cross-sectional view of the display apparatus, taken along a line I-I′ of FIG. 1;

FIG. 3 is a schematic cross-sectional view of a display panel of a display apparatus according to some embodiments;

FIGS. 4A and 4B are each a schematic cross-sectional view of a display apparatus according to some embodiments;

FIG. 5 is an equivalent circuit diagram of a pixel circuit, which is electrically connected to a light-emitting device of a display apparatus, and a sensor circuit, which is electrically connected to a light-receiving device of the display apparatus, according to some embodiments;

FIG. 6 is a schematic plan view of a portion of a display apparatus according to some embodiments, which corresponds to an enlarged schematic plan view of a region A of FIG. 1;

FIG. 7 is a schematic cross-sectional view of the display apparatus, taken along a line II-II′ of FIG. 6;

FIG. 8 is a schematic cross-sectional view of a portion of a display apparatus according to some embodiments;

FIG. 9 is a schematic cross-sectional view of a portion of a display apparatus according to some embodiments;

FIG. 10 is a schematic plan view of a portion of a display apparatus according to some embodiments;

FIG. 11 is a schematic cross-sectional view of a portion of a display apparatus according to some embodiments;

FIG. 12 is a schematic plan view of a portion of a display apparatus according to some embodiments; and

FIG. 13 is a schematic cross-sectional view of a portion of a display apparatus according to some embodiments.

### DETAILED DESCRIPTION

Reference will now be made in more detail to aspects of some embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or any combination of a, b, and/or c.

As the disclosure allows for various changes and numerous embodiments, particular embodiments will be illustrated in the drawings and described in more detail in the written description. Characteristics and features of the disclosure and methods of achieving the same will be apparent with reference to embodiments and drawings described below in more detail. However, the disclosure may be implemented in various forms, not by being limited to the embodiments presented below.

Hereinafter, aspects of some embodiments will be described in more detail with reference to the accompanying drawings, and in the description with reference to the drawings, the same or corresponding elements are indicated by the same reference numerals and redundant descriptions thereof are omitted.

In the following embodiments, while terms such as “first” and “second” are used to describe various elements, these elements are not limited by these terms. These terms are only used to distinguish one element from another element.

In the following embodiments, an expression used in the singular encompasses the expression of the plural, unless it has a clearly different meaning in the context.

In the following embodiments, terms such as “comprise,” “include,” and “have” specify the presence of stated features or elements, but do not preclude the presence or addition of one or more other features or elements.

In the following embodiments, when a layer, region, or element is referred to as being “on” another layer, region, or element, it can be directly or indirectly on the other layer, region, or element. That is, for example, intervening layers, regions, or elements may be present.

Sizes of elements in the drawings may be exaggerated or reduced for convenience of description. For example, because sizes and thicknesses of elements in the drawings are arbitrarily illustrated for convenience of description, the embodiments are not limited thereto.

When an embodiment may be implemented differently, a certain process order may be performed differently from the described order. For example, two processes described in succession may be performed substantially simultaneously, or may be performed in an order opposite to the order described.

In the following embodiments, when a layer, region, or element is referred to as being “connected to” another layer, region, or element, it can be directly or indirectly connected to the other layer, region, or element. That is, for example, intervening layers, regions, or elements may be present. For example, when a layer, region, or element is referred to as being “electrically connected to” another layer, region, or element, it can be directly or indirectly electrically connected to the other layer, region, or element. That is, for example, intervening layers, regions, or elements may be present.

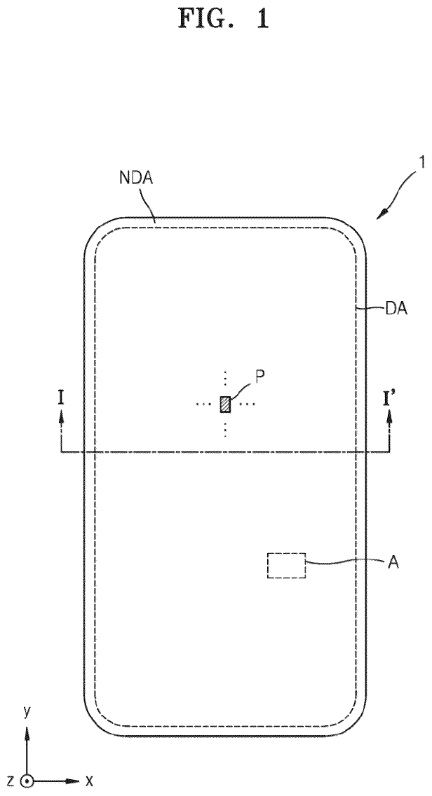

FIG. 1 is a schematic plan view of a portion of a display apparatus 1 according to some embodiments.

Referring to FIG. 1, the display apparatus 1 may include a display area DA and a peripheral area NDA outside the display area DA. A plurality of pixels P including a display element may be arranged in the display area DA, and the display apparatus 1 may display images by using light emitted from the plurality of pixels P arranged in the display area DA. The peripheral area NDA may be a type of non-display area in which display elements are not arranged, and the display area DA may be entirely surrounded by the peripheral area NDA. That is, according to some embodiments, the peripheral area NDA may surround (e.g., in a periphery or outside a footprint of) the display area DA.

The display apparatus 1 shown in FIG. 1 has a flat display surface, but embodiments according to the present disclosure are not limited thereto. According to some embodiments, the display apparatus 1 may include a three-dimensional display surface or a curved display surface.

When the display apparatus 1 includes a three-dimensional display surface, the display apparatus 1 may include a plurality of display areas indicating different directions from each other and may include, for example, a polygonal column-shaped display surface. According to some embodiments, when the display apparatus 1 includes a curved display surface, the display apparatus 1 may be implemented in various forms, such as a flexible display apparatus, a foldable display apparatus, and a rollable display apparatus.

Also, according to some embodiments, the display apparatus 1 shown in FIG. 1 may be applied to a mobile phone terminal. According to some embodiments, electronic modules, a camera module, and a power module, which are mounted on a main board, may be arranged in a bracket/case along with the display apparatus 1 to form a mobile phone terminal. The display apparatus 1 according to the disclosure may be applied to large electronic devices, such as a television and a monitor, as well as small and medium-sized electronic devices, such as a tablet, a vehicle navigation system, a game console, and a smartwatch.

The display area DA of the display apparatus 1 shown in FIG. 1 has a quadrangular shape with round corners. However, according to some embodiments, the display area DA may have a circular shape, an oval shape, an irregular shape, or a polygonal shape, such as a triangle or a pentagon.

Hereinafter, an organic light-emitting display apparatus is described as an example of the display apparatus 1 according to some embodiments, but the display apparatus 1 of the disclosure is not limited thereto. According to some embodiments, the display apparatus 1 of the disclosure may be an inorganic light-emitting display apparatus (or inorganic electroluminescent (EL) display apparatus) or a quantum dot light-emitting display apparatus. For example, an emission layer of a display element included in the display apparatus 1 may include an organic material, an inorganic material, a quantum dot, an organic material and a quantum dot, or an inorganic material and a quantum dot.

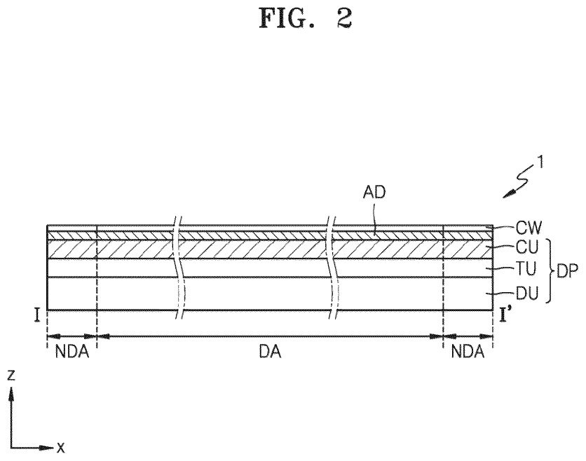

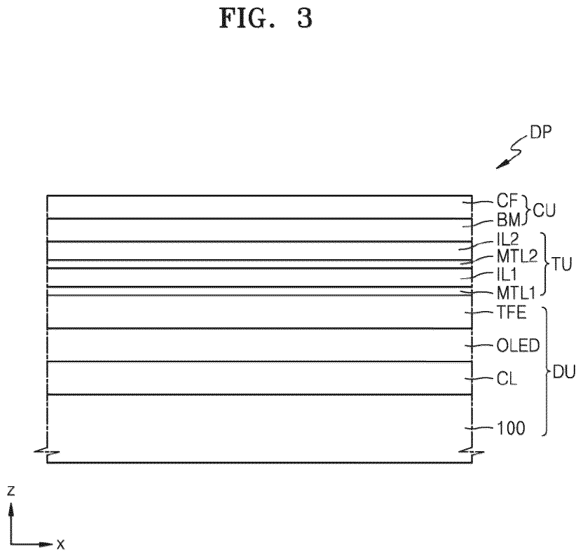

FIG. 2 is a schematic cross-sectional view of the display apparatus 1, taken along a line I-I′ of FIG. 1, and FIG. 3 is a schematic cross-sectional view of a display panel DP of the display apparatus 1 according to some embodiments. FIGS. 2 and 3 are shown in a simplified manner to describe a stacking relationship between functional panels and/or functional layers that form the display apparatus 1.

Referring to FIG. 2, the display apparatus 1 according to some embodiments may include a display layer DU, an input-sensing layer TU, an optical functional layer, a color filter member CU, and a cover window CW. At least some elements of the display layer DU, the input-sensing layer TU, the color filter member CU, and the cover window CW may be formed through a continuous process, or at least some elements may be coupled to each other by an adhesive member AD. The adhesive member AD of FIG. 2 may be an optically clear adhesive (OCA). However, embodiments according to the present disclosure are not limited thereto, and the adhesive member AD described below may include a typical adhesive or sticking agent. According to some embodiments, the cover window CW may be replaced with another element or omitted.

According to some embodiments, the input-sensing layer TU may be located directly on the display layer DU. As used herein, the expression “an element B is directly located on an element A” means that no separate adhesive layers/adhesive materials are arranged between the element A and the element B. The element B is formed on a base surface provided by the element A through a continuous process after the element A is formed.

According to some embodiments, a structure including the display layer DU, the input-sensing layer TU, and the color filter member CU may be defined as a display panel DP. For example, as shown in FIG. 2, the adhesive member AD may be arranged between the display panel DP and the cover window CW.

The display layer DU may generate images, and the input-sensing layer TU may obtain coordinate information of an external input (e.g., a touch event). Although not separately shown, the display panel DP according to some embodiments may further include a protective member located on a lower surface of the display layer DU. The protective member and the display layer DU may be coupled to each other through an adhesive member. According to some embodiments, an optical functional layer may be additionally located on the input-sensing layer TU. The optical functional layer may relatively improve light efficiency. The optical functional layer may relatively improve the front light efficiency and/or side visibility of light emitted from a light-emitting device, for example, an organic light-emitting diode.

According to some embodiments, the color filter member CU may be arranged between the input-sensing layer TU and the cover window CW. The color filter member CU may include a color filter provided to correspond to an emission area of each pixel P and a light-blocking layer provided to correspond to a non-emission area between pixels P.

Hereinafter, the structures of the display layer DU, the input-sensing layer TU, and the color filter member CU are described in more detail with reference to FIG. 3. Referring to FIG. 3, the display panel DP may include the display layer DU, the input-sensing layer TU, and the color filter member CU.

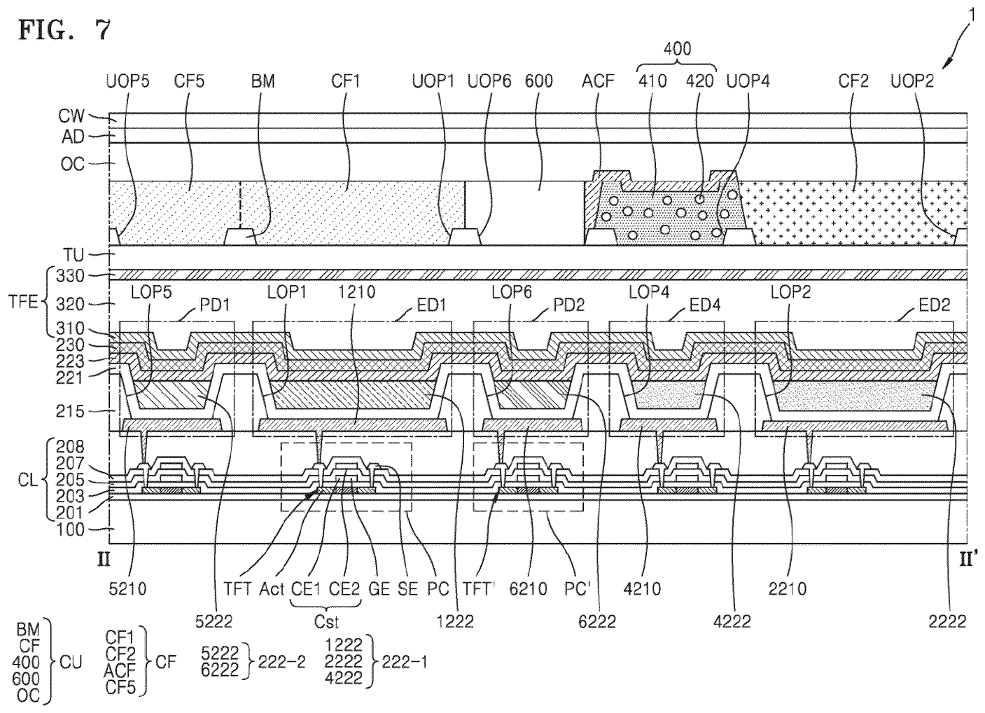

The display layer DU may include a circuit layer CL, a light-emitting device (e.g., an organic light-emitting diode OLED), and a thin-film encapsulation layer TFE, which are sequentially arranged on a substrate 100. The input-sensing layer TU may be directly located on the thin-film encapsulation layer TFE. The thin-film encapsulation layer TFE may include at least one organic encapsulation layer 320 (see FIG. 7) and thus may provide a flatter base surface. Accordingly, even when elements of the input-sensing layer TU to be described below are formed through a continuous process, a defect rate may be reduced.

The input-sensing layer TU may have a multi-layer structure. The input-sensing layer TU may include a sensing electrode, a trace line connected to the sensing electrode, and at least one insulating layer. The input-sensing layer TU may sense an external input by, for example, a capacitive method. An operating method of the input-sensing layer TU described herein is not limited. According to some embodiments, the input-sensing layer TU may sense an external input by an electromagnetic induction method or a pressure sensing method.

As shown in FIG. 3, the input-sensing layer TU according to some embodiments may include a first conductive layer MTL1, a first inorganic insulating layer IL1, a second conductive layer MTL2, and a second inorganic insulating layer IL2. According to some embodiments, an additional insulating layer may be arranged between the first conductive layer MTL1 and the thin-film encapsulation layer TFE.

According to some embodiments, each of the first conductive layer MTL1 and the second conductive layer MTL2 may have a single-layer structure or a multi-layer structure in which multiple layers are stacked. A conductive layer having a single-layer structure may include a metal layer or a transparent conductive layer. The metal layer may include molybdenum (Mo), silver (Ag), titanium (Ti), copper (Cu), aluminum (Al), and an alloy thereof. The transparent conductive layer may include a transparent conductive oxide, such as indium tin oxide (ITO), indium zinc oxide (IZO), zinc oxide (ZnO), or indium tin zinc oxide (ITZO). Also, the transparent conductive layer may include a conductive polymer, such as poly (3,4-ethylenedioxythiophene) (PEDOT), metal nanowires, and graphene. A conductive layer having a multi-layer structure may include multiple metal layers. The multiple metal layers may have, for example, a three-layer structure of Ti/Al/Ti. The conductive layer having a multi-layer structure may include at least one metal layer and at least one transparent conductive layer.

Each of the first conductive layer MTL1 and the second conductive layer MTL2 may include a plurality of patterns. Hereinafter, the first conductive layer MTL1 may be understood as including first conductive patterns, and the second conductive layer MTL2 may be understood as including second conductive patterns. The first conductive patterns and the second conductive patterns may form a sensing electrode. According to some embodiments, the sensing electrode may have a mesh shape to prevent or reduce visibility to users.

Each of the first inorganic insulating layer IL1 and the second inorganic insulating layer IL2 may have a single-layer or multi-layer structure. Each of the first inorganic insulating layer IL1 and the second inorganic insulating layer IL2 may include an inorganic material or a composite material. For example, at least one of the first inorganic insulating layer IL1 or the second inorganic insulating layer IL2 may include an inorganic film. The inorganic film may include at least one of aluminum oxide, titanium oxide, silicon oxide, silicon oxynitride, zirconium oxide, or hafnium oxide. According to some embodiments, the first inorganic insulating layer IL1 and/or the second inorganic insulating layer IL2 may be replaced with an organic insulating layer.

According to some embodiments, as shown in FIG. 3, the color filter member CU may be directly located on the input-sensing layer TU. The color filter member CU may include a light-blocking layer BM and a color filter layer CF on the light-blocking layer BM. The light-blocking layer BM may be a black matrix that at least partially absorbs externally reflected light or internally reflected light. The color filter layer CF may have a color corresponding to light emitted from a light-emitting layer located below the color filter layer CF.

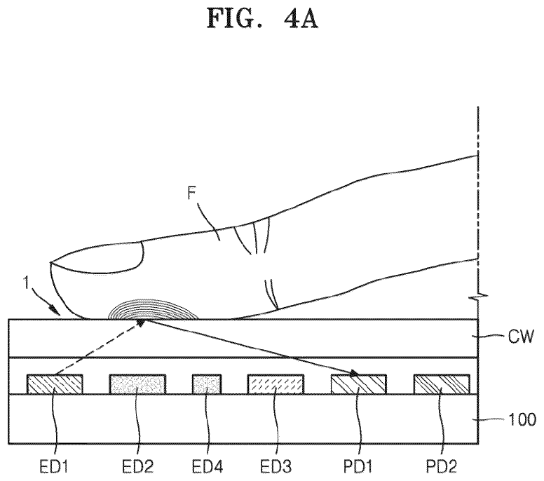

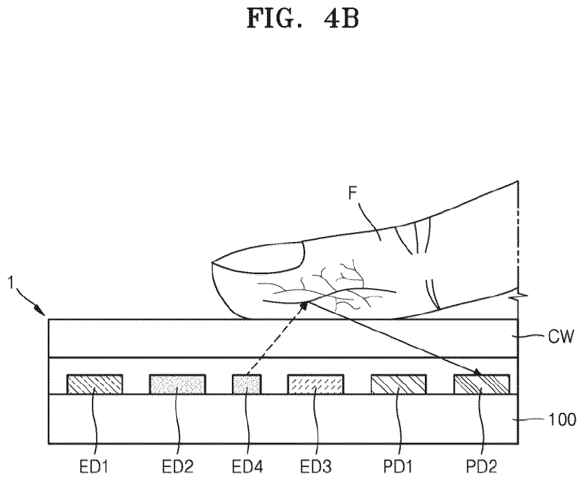

FIGS. 4A and 4B are each a schematic cross-sectional view of the display apparatus 1 according to some embodiments.

Referring to FIGS. 4A and 4B, the display apparatus 1 according to some embodiments may further include an optical sensor, in addition to the plurality of pixels P (see FIG. 1). Each of the plurality of pixels P (see FIG. 1) may include at least one of a first light-emitting device ED1, a second light-emitting device ED2, or a third light-emitting device ED3, and the optical sensor may include a first light-receiving device PD1 and a second light-receiving device PD2. The first light-emitting device ED1, the second light-emitting device ED2, and the third light-emitting device ED3 may emit light of different colors from each other. For example, the first light-emitting device ED1 may emit green light, the second light-emitting device ED2 may emit blue light, and the third light-emitting device ED3 may emit red light.

According to some embodiments, the display apparatus 1 may further include an auxiliary light-emitting device ED4, in addition to the first to third light-emitting devices ED1, ED2, and ED3. An emission layer of the auxiliary light-emitting device ED4 may emit light of the same color as that of light emitted from one of the first light-emitting device ED1, the second light-emitting device ED2, and the third light-emitting device ED3. For example, the emission layer of the auxiliary light-emitting device ED4 may emit blue light identical to that emitted from the second light-emitting device ED2. However, a wavelength conversion pattern, which is described in more detail below with reference to FIG. 7, may be located on the auxiliary light-emitting device ED4, and thus, an emission area of the auxiliary light-emitting device ED4 may emit light in the infrared wavelength band. According to some embodiments, the first to third light-emitting devices ED1, ED2, and ED3 and the auxiliary light-emitting device ED4 may be driven independently of each other.

As shown in FIG. 4A, the display apparatus 1 may have a function of sensing an object in contact with the cover window CW, for example, a fingerprint of a finger F. Among light emitted from at least one of the first light-emitting device ED1, the second light-emitting device ED2, or the third light-emitting device ED3, at least a portion of reflected light reflected by a user's fingerprint may be re-incident on the first light-receiving device PD1, and thus, the first light-receiving device PD1 may detect the reflected light. For example, green light emitted from the first light-emitting device ED1 may be reflected by an object in contact with the cover window CW and be re-incident on the first light-receiving device PD1, and thus, the first light-receiving device PD1 may detect the re-incident green light.

Also, as shown in FIG. 4B, the display apparatus 1 may have a function of sensing biometric information or touch information of an object in contact with the cover window CW, for example, the finger F. For example, light emitted from at least one of the second light-emitting device ED2 or the auxiliary light-emitting device ED4 may be converted into light in the infrared wavelength band through a wavelength conversion pattern to be described below. Light in the infrared wavelength band has a longer wavelength and thus may penetrate deeper into an object than light in the visible light wavelength band, thereby securing more diverse sensing information, such as biometric information. For example, light emitted from the auxiliary light-emitting device ED4 may be converted into light in the infrared wavelength band and then be reflected by an object in contact with the cover window CW and be re-incident on the second light-receiving device PD2, and thus, the second light-receiving device PD2 may detect the light in the infrared wavelength band. Accordingly, the optical sensor including the second light-receiving device PD2 may sense biometric information or touch information including a user's oxygen saturation, pulse, and blood pressure.

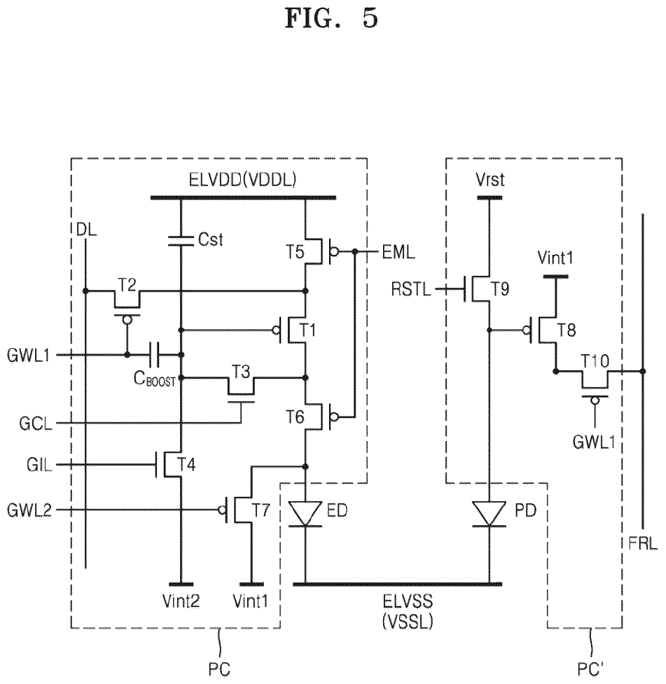

FIG. 5 is an equivalent circuit diagram of a pixel circuit PC, which is electrically connected to a light-emitting device ED of the display apparatus 1, and a sensor circuit PC′, which is electrically connected to a light-receiving device PD of the display apparatus 1, according to some embodiments. Although FIG. 5 illustrates various components in a pixel circuit PC and a sensor circuit PC′ according to some embodiments, embodiments according to the present disclosure are not limited thereto, and according to various embodiments, the pixel circuit PC and the sensor circuit PC′ may include additional components or fewer components without departing from the spirit and scope of embodiments according to the present disclosure.

Referring to FIG. 5, the pixel P (see FIG. 1) may include the light-emitting device ED and the pixel circuit PC that controls the amount of light emitted from the light-emitting device ED, and the optical sensor may include the light-receiving device PD and the sensor circuit PC′ that controls the amount of light received by the light-receiving device PD.

Each pixel circuit PC may be connected to a scan start line GIL, a scan control line GCL, a first scan write line GWL1, a second scan write line GWL2, an emission line EML, and a data line DL. Also, each pixel circuit PC may be connected to a first driving voltage line VDDL through which a first driving voltage ELVDD is applied, a second driving voltage line VSSL through which a second driving voltage ELVSS is applied, a first initialization voltage line through which a first initialization voltage Vint1 is applied, and a second initialization voltage line through which a second initialization voltage Vint2 is applied.

Each sensor circuit PC′ may be connected to the first scan write line GWL1, a reset line RSTL, and a fingerprint-sensing line FRL. Also, each sensor circuit PC′ may be connected to the second driving voltage line VSSL through which the second driving voltage ELVSS is applied, a reset voltage line through which a reset voltage Vrst is applied, and the first initialization voltage line through which the first initialization voltage Vint1 is applied.

Each pixel circuit PC may include a plurality of transistors and at least one capacitor and may be connected to the light-emitting device ED. The plurality of transistors may include first to seventh transistors T1, T2, T3, T4, T5, T6, and T7. Among the plurality of transistors, the first transistor T1 may be a driving transistor, and the second to seventh transistors T2 to T7 may be transistors serving as switch devices, which are turned on or turned off according to scan signals applied to respective gate electrodes of the transistors.

The first transistor T1 may include a gate electrode, a first electrode, and a second electrode. The gate electrode of the first transistor T1 may be connected to a first electrode of the third transistor T3 and one electrode of a storage capacitor Cst, the first electrode of the first transistor T1 may be connected to a second electrode of the second transistor T2 and a second electrode of the fifth transistor T5, and the second electrode of the first transistor T1 may be connected to a second electrode of the third transistor T3 and a first electrode of the sixth transistor T6.

The light-emitting device ED may emit light according to a driving current. The amount of light emitted from the light-emitting device ED may be proportional to the driving current. The light-emitting device ED may be an organic light-emitting diode including a pixel electrode, a counter electrode, and an organic emission layer arranged between the pixel electrode and the counter electrode. Alternatively, the light-emitting device ED may be an inorganic light-emitting diode including an inorganic emission layer arranged between a pixel electrode and a counter electrode, or may be a quantum dot light-emitting diode including a quantum dot emission layer arranged between a pixel electrode and a counter electrode. Also, the light-emitting device ED may be a micro-light-emitting diode. The pixel electrode of the light-emitting device ED may be connected to a second electrode of the sixth transistor T6 and a second electrode of the seventh transistor T7, and the counter electrode of the light-emitting device ED may be connected to the second driving voltage line VSSL.

The second transistor T2 may be turned on by a scan signal of the first scan write line GWL1 to connect the first electrode of the first transistor T1 and the data line DL to each other. A gate electrode of the second transistor T2 may be connected to the first scan write line GWL1, a first electrode of the second transistor T2 may be connected to the data line DL, and the second electrode of the second transistor T2 may be connected to the first electrode of the first transistor T1.

The third transistor T3 may be turned on by a scan signal of the scan control line GCL to connect the gate electrode and the second electrode of the first transistor T1 to each other. That is, when the third transistor T3 is turned on, the gate electrode and the second electrode of the first transistor T1 may be connected to each other, and thus, the first transistor T1 may be driven as a diode. A gate electrode of the third transistor T3 may be connected to the scan control line GCL, the first electrode of the third transistor T3 may be connected to the second electrode of the first transistor T1, and the second electrode of the third transistor T3 may be connected to the gate electrode of the first transistor T1.

The fourth transistor T4 may be turned on by a scan signal of the scan start line GIL to connect the gate electrode of the first transistor T1 and the second initialization voltage line to each other. In this case, the gate electrode of the first transistor T1 may be discharged to the second initialization voltage Vint2 of the second initialization voltage line. A gate electrode of the fourth transistor T4 may be connected to the scan start line GIL, a first electrode of the fourth transistor T4 may be connected to the second initialization voltage line, and a second electrode of the fourth transistor T4 may be connected to the gate electrode of the first transistor T1.

The fifth transistor T5 may be turned on by an emission signal of the emission line EML to connect the first electrode of the first transistor T1 and the first driving voltage line VDDL to each other. A gate electrode of the fifth transistor T5 may be connected to the emission line EML, a first electrode of the fifth transistor T5 may be connected to the first driving voltage line VDDL, and the second electrode of the fifth transistor T5 may be connected to the first electrode of the first transistor T1.

The sixth transistor T6 may be turned on by an emission signal of the emission line EML to connect the second electrode of the first transistor T1 and the pixel electrode of the light-emitting device ED to each other. A gate electrode of the sixth transistor T6 may be connected to the emission line EML, the first electrode of the sixth transistor T6 may be connected to the second electrode of the first transistor T1, and the second electrode of the sixth transistor T6 may be connected to the pixel electrode of the lightemitting device ED. When both the fifth transistor T5 and the sixth transistor T6 are turned on, a driving current may be supplied to the light-emitting device ED.

The seventh transistor T7 may be turned on by a scan signal of the second scan write line GWL2 to connect the first initialization voltage line and the pixel electrode of the light-emitting device ED to each other. In this case, the pixel electrode of the light-emitting device ED may be discharged to the first initialization voltage Vint1. A gate electrode of the seventh transistor T7 may be connected to the second scan write line GWL2, a first electrode of the seventh transistor T7 may be connected to the first initialization voltage line, and the second electrode of the seventh transistor T7 may be connected to the pixel electrode of the light-emitting device ED.

The storage capacitor Cst may be formed between the gate electrode of the first transistor T1 and the first driving voltage line VDDL. One electrode of the storage capacitor Cst may be connected to the gate electrode of the first transistor T1, and the other electrode of the storage capacitor Cst may be connected to the first driving voltage line VDDL. As a result, the storage capacitor Cst may maintain an electric potential difference between the gate electrode of the first transistor T1 and the first driving voltage line VDDL.

A boost capacitor CBoost may be formed between the gate electrode of the second transistor T2 and the gate electrode of the first transistor T1. One electrode of the boost capacitor CBOOST may be connected to the first scan write line GWL1, which is connected to the gate electrode of the second transistor T2, and the other electrode of the boost capacitor CBoost may be connected to the gate electrode of the first transistor T1 and one electrode of the storage capacitor Cst. The boost capacitor CBOOST may be a boosting capacitor and, when a signal of the first scan write line GWL1 is a voltage that turns off the second transistor T2, may increase a voltage of a node to reduce a voltage displaying black (a black voltage).

Each sensor circuit PC′ may include a plurality of transistors and may be connected to the light-receiving device PD. The plurality of transistors may include eighth to tenth transistors T8, T9, and T10. Among the plurality of transistors, the eighth transistor T8 may be a driving transistor, and the ninth transistor T9 and the tenth transistor T10 may be transistors serving as switch devices, which are turned on or turned off according to scan signals applied to respective gate electrodes of the transistors.

When a plurality of light-emitting devices ED and a plurality of light-receiving devices PD are arranged in one display apparatus 1 (see FIG. 1), a voltage wire or a signal wire for driving the light-emitting device ED may be commonly used in driving the light-receiving device PD. That is, by reducing the additional arrangement of voltage wires or signal wires for driving the plurality of light-receiving devices PD in the display apparatus 1 (see FIG. 1), the resolution of the display apparatus 1 (see FIG. 1) may be secured, and the peripheral area NDA (see FIG. 1) may be reduced. For example, a signal wire connected to the gate electrode of the second transistor T2 of the pixel P (see FIG. 1) may be commonly used with a signal wire connected to a gate electrode of the tenth transistor T10 of the optical sensor. That is, the gate electrode of the second transistor T2 and the gate electrode of the tenth transistor T10 may be connected to the first scan write line GWL1. As another example, the second driving voltage line VSSL may be a common voltage wire connected to the counter electrode of the light-emitting device ED and a counter electrode of the light-receiving device PD. As another example, the first initialization voltage line through which the first initialization voltage Vint1 is applied may be a common voltage wire connected to a second electrode of the eighth transistor T8 of the optical sensor and the second electrode of the seventh transistor T7.

Each light-receiving device PD may be a light-receiving diode including a sensing electrode, a counter electrode, and a photoelectric conversion layer arranged between the sensing electrode and the counter electrode. Each light-receiving device PD may convert light incident from the outside into an electrical signal. The light-receiving device PD may be a light-receiving diode or a phototransistor including a pn-type or pin-type inorganic material. Alternatively, the light-receiving device PD may be an organic light-receiving diode including an electron-donating material that generates donor ions and an electron-accepting material that generates acceptor ions.

When the light-receiving device PD is exposed to external light, photocharges may be generated, and the generated photocharges may be accumulated in the sensing electrode of the light-receiving device PD. In this case, a voltage of a node electrically connected to the sensing electrode may increase. When the light-receiving device PD and the fingerprint-sensing line FRL are connected to each other according to the turn-on of the eighth transistor T8 and the tenth transistor T10, a current may flow in the fingerprint-sensing line FRL in proportion to a voltage of a node in which charges are accumulated.

The eighth transistor T8 may be turned on by a voltage applied to a gate electrode of the eighth transistor T8 to connect the first initialization voltage line and a first electrode of the tenth transistor T10 to each other. In this case, a second electrode of the tenth transistor T10 may be discharged to the first initialization voltage Vint1. The gate electrode of the eighth transistor T8 may be connected to a node between the ninth transistor T9 and the light-receiving device PD, a first electrode of the eighth transistor T8 may be connected to the first initialization voltage line, and the second electrode of the eighth transistor T8 may be connected to the first electrode of the tenth transistor T10. The eighth transistor T8 may be a source follower amplifier that generates a source-drain current in proportion to the amount of charge of a node input to the gate electrode of the eighth transistor T8. The first electrode of the eighth transistor T8 may be connected to the first driving voltage line VDDL or the second initialization voltage line.

The tenth transistor T10 may be turned on by a scan signal of the first scan write line GWL1 to connect the second electrode of the eighth transistor T8 and the fingerprint-sensing line FRL to each other. The fingerprint-sensing line FRL may be configured to transmit a fingerprint-sensing signal to a read-out circuit. The gate electrode of the tenth transistor T10 may be connected to the first scan write line

GWL1, the first electrode of the tenth transistor T10 may be connected to the second electrode of the eighth transistor T8, and the second electrode of the tenth transistor T10 may be connected to the fingerprint-sensing line FRL.

The ninth transistor T9 may be turned on by a reset signal of the reset line RSTL to reset a node connected to the gate electrode of the eighth transistor T8 to the reset voltage Vrst. A gate electrode of the ninth transistor T9 may be connected to the reset line RSTL, a first electrode of the ninth transistor T9 may be connected to the reset voltage line, and a second electrode of the ninth transistor T9 may be connected to a node connecting the light-receiving device PD and the eighth transistor T8 to each other. When a reset driver that outputs a reset signal of the reset line RSTL is omitted, the ninth transistor T9 may be turned on by a scan signal.

When the first electrode of each of the first to tenth transistors T1, T2, T3, T4, T5, T6, T7, T8, T9, and T10 is a source electrode, the second electrode of each of the first to tenth transistors T1, T2, T3, T4, T5, T6, T7, T8, T9, and T10 may be a drain electrode. Alternatively, when the first electrode of each of the first to tenth transistors T1, T2, T3, T4, T5, T6, T7, T8, T9, and T10 is a drain electrode, the second electrode of each of the first to tenth transistors T1, T2, T3, T4, T5, T6, T7, T8, T9, and T10 may be a source electrode.

An active layer of each of the first to tenth transistors T1, T2, T3, T4, T5, T6, T7, T8, T9, and T10 may include one of polysilicon, amorphous silicon, and an oxide semiconductor. For example, the first and second transistors T1 and T2, the fifth to eighth transistors T5, T6, T7, and T8, and the tenth transistor T10 may be P-type transistors. In this case, the active layer of each of the first and second transistors T1 and T2, the fifth to eighth transistors T5, T6, T7, and T8, and the tenth transistor T10 may include polysilicon. Also, each of the third transistor T3, the fourth transistor T4, and the ninth transistor T9 may be an N-type transistor that includes an active layer of an oxide semiconductor.

However, embodiments according to the present disclosure are not limited thereto, and each of the first to tenth transistors T1, T2, T3, T4, T5, T6, T7, T8, T9, and T10 may be a P-type transistor. As another example, the eighth to tenth transistors T8, T9, and T10 may be formed as P-type transistors.

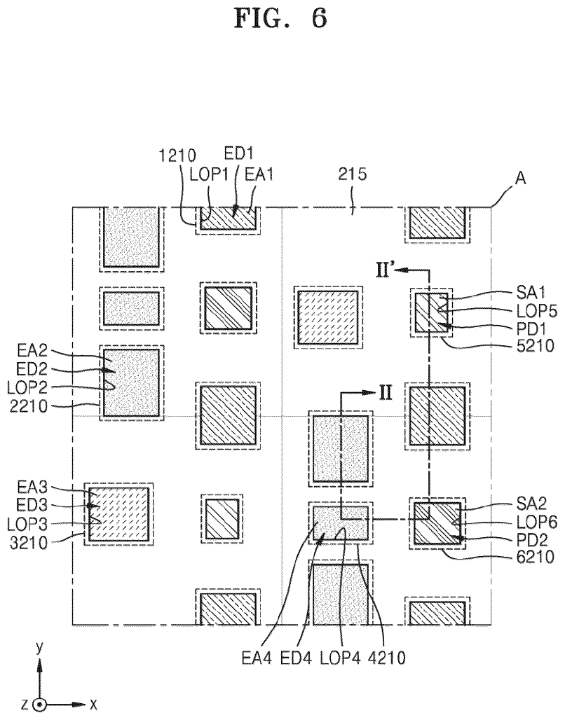

FIG. 6 is a schematic plan view of a portion of the display apparatus 1 according to some embodiments. For example, FIG. 6 is an enlarged schematic plan view of a region A of FIG. 1. FIG. 6 shows a plan view over a bank layer 215 for convenience.

Referring to FIG. 6, the display apparatus 1 may include a plurality of light-emitting devices, a plurality of light-receiving devices, and a plurality of auxiliary light-emitting devices. The plurality of light-emitting devices may include the first light-emitting device ED1, the second light-emitting device ED2, and the third light-emitting device ED3, and the plurality of light-receiving devices may include the first light-receiving device PD1 and the second light-receiving device PD2. The plurality of auxiliary light-emitting devices may include the auxiliary light-emitting device ED4.

The first light-emitting device ED1, the second light-emitting device ED2, and the third light-emitting device ED3 may emit light of different colors from each other. For example, the first light-emitting device ED1 may emit green light, the second light-emitting device ED2 may emit blue light, and the third light-emitting device ED3 may emit red light. The red light may be light in a wavelength band of about 580 nm to about 780 nm, the blue light may be light in a wavelength band of about 380 nm to about 495 nm, and the green light may be light in a wavelength band of about 495 nm to about 580 nm. The first light-receiving device PD1 may absorb light in the visible light wavelength band. That is, the first light-receiving device PD1 may sense an object by detecting light that is emitted from the first light-emitting device ED1, the second light-emitting device ED2, and/or the third light-emitting device ED3 and reflected by the object.

An emission layer of the auxiliary light-emitting device ED4 may emit light of the same color as that of light emitted from one of the first light-emitting device ED1, the second light-emitting device ED2, and the third light-emitting device ED3. For example, the emission layer of the auxiliary light-emitting device ED4 may emit light in a wavelength band of about 380 nm to about 495 nm, like the second light-emitting device ED2 that emits blue light. However, a wavelength conversion pattern 400 (see FIG. 7) to be described below may be located on the auxiliary light-emitting device ED4. Accordingly, light in the visible light wavelength band emitted from the emission layer of the auxiliary light-emitting device ED4 may be converted into light in the infrared wavelength band and emitted through the wavelength conversion pattern 400 (see FIG. 7). The second light-receiving device PD2 may absorb light in the infrared wavelength band. That is, the second light-receiving device PD2 may sense an object by detecting light that is emitted from the auxiliary light-emitting device ED4, converted into the infrared wavelength band, and then reflected by the object.

Each light-emitting device may include a pixel electrode, a counter electrode, and an intermediate layer arranged therebetween, and each light-receiving device may include a sensing electrode, a counter electrode, and an intermediate layer arranged therebetween. Accordingly, the first light-emitting device ED1 may include a first pixel electrode 1210, the second light-emitting device ED2 may include a second pixel electrode 2210, the third light-emitting device ED3 may include a third pixel electrode 3210, and the auxiliary light-emitting device ED4 may include a fourth pixel electrode 4210. The first light-receiving device PD1 may include a first sensing electrode 5210, and the second light-receiving device PD2 may include a second sensing electrode 6210. The first pixel electrode 1210, the second pixel electrode 2210, the third pixel electrode 3210, the fourth pixel electrode 4210, the first sensing electrode 5210, and the second sensing electrode 6210 may be arranged apart from each other on the substrate 100 (see FIG. 7). As used herein, the expression “in a plan view” refers to a plan view taken in a direction perpendicular to the substrate 100. That is, the expression “A and B apart from each other in a plan view” refers to “A and B apart from each other when viewed in a direction perpendicular to the substrate 100.”

The bank layer 215 may be located on the first pixel electrode 1210, the second pixel electrode 2210, the third pixel electrode 3210, the fourth pixel electrode 4210, the first sensing electrode 5210, and the second sensing electrode 6210 and may cover an edge of each of the first pixel electrode 1210, the second pixel electrode 2210, the third pixel electrode 3210, the fourth pixel electrode 4210, the first sensing electrode 5210, and the second sensing electrode 6210. That is, the bank layer 215 may include a plurality of bank layer openings respectively exposing central portions of the plurality of pixel electrodes and the plurality of sensing electrodes. For example, the bank layer 215 may have a first bank layer opening LOP1 exposing a central portion of the first pixel electrode 1210, a second bank layer opening LOP2 exposing a central portion of the second pixel electrode 2210, a third bank layer opening LOP3 exposing a central portion of the third pixel electrode 3210, a fourth bank layer opening LOP4 exposing a central portion of the fourth pixel electrode 4210, a fifth bank layer opening LOP5 exposing a central portion of the first sensing electrode 5210, and a sixth bank layer opening LOP6 exposing a central portion of the second sensing electrode 6210.

According to some embodiments, emission layers that emit light may be respectively arranged in the first to fourth bank layer openings LOP1, LOP2, LOP3, and LOP4 of the bank layer 215, and active layers that detect light may be respectively arranged in the fifth bank layer opening LOP5 and the sixth bank layer opening LOP6 of the bank layer 215. A counter electrode may be located on the emission layers and the active layers. As described above, a stacked structure of a pixel electrode, an emission layer, and a counter electrode may form one light-emitting device. Also, as described above, a stacked structure of a sensing electrode, an active layer, and a counter electrode may form one light-receiving device. One bank layer opening of the bank layer 215 may correspond to one light-emitting device and may define one emission area. Alternatively, one bank layer opening of the bank layer 215 may correspond to one light-receiving device and may define one sensing area.

For example, an emission layer that emits green light may be arranged in the first bank layer opening LOP1, and thus, the first bank layer opening LOP1 may define a first emission area EA1. Similarly, an emission layer that emits blue light may be arranged in the second bank layer opening LOP2, and thus, the second bank layer opening LOP2 may define a second emission area EA2. An emission layer that emits red light may be arranged in the third bank layer opening LOP3, and thus, the third bank layer opening LOP3 may define a third emission area EA3. As described above, the emission layer of the auxiliary light-emitting device ED4 may emit light of the same color as that of light emitted from the emission layer of the second light-emitting device ED2. Accordingly, an emission layer that emits blue light may also be arranged in the fourth bank layer opening LOP4, and thus, the fourth bank layer opening LOP4 may define a fourth emission area EA4. An active layer that detects light in the visible light wavelength band may be arranged in the fifth bank layer opening LOP5, and thus, the fifth bank layer opening LOP5 may define a first sensing area SA1. An active layer that detects light in the infrared wavelength band may be arranged in the sixth bank layer opening LOP6, and thus, the sixth bank layer opening LOP6 may define a second sensing area SA2.

Accordingly, the area size of the first bank layer opening LOP1 may be the same as the area size of the first emission area EA1. The area size of the second bank layer opening LOP2 may be the same as the area size of the second emission area EA2, the area size of the third bank layer opening LOP3 may be the same as the area size of the third emission area EA3, and the area size of the fourth bank layer opening LOP4 may be the same as the area size of the fourth emission area EA4. Likewise, the area size of the fifth bank layer opening LOP5 may be the same as the area size of the first sensing area SA1, and the area size of the sixth bank layer opening LOP6 may be the same as the area size of the second sensing area SA2.

According to some embodiments, the area size of the fourth emission area EA4 may be less than the area size of the second emission area EA2. The auxiliary light-emitting device ED4 may emit blue light, like the second light-emitting device ED2. However, due to a wavelength conversion pattern located thereon, the fourth emission area EA4 may emit light in the infrared wavelength band. Because light in the infrared wavelength band is not visible to a user using the display apparatus 1 (see FIG. 1) and is emitted for sensing, a large emission area may not be needed. Accordingly, the fourth emission area EA4 may be designed to have a smaller area than the second emission area EA2 in a plan view.

Each of the first to sixth bank layer openings LOP1, LOP2, LOP3, LOP4, LOP5, and LOP6 may have a polygonal shape when viewed in a direction (a z-axis direction) perpendicular to the substrate 100 (see to FIG. 7). In other words, each of the first to fourth emission areas EA1, EA2, EA3, and EA4, the first sensing area SA1, and the second sensing area SA2 may have a polygonal shape when viewed in the direction (the z-axis direction) perpendicular to the substrate 100. FIG. 6 shows that each of the first to fourth emission areas EA1, EA2, EA3, and EA4, the first sensing area SA1, and the second sensing area SA2 has a quadrangular shape when viewed in the direction (the z-axis direction) perpendicular to the substrate 100 (see FIG. 7). However, embodiments according to the present disclosure are not limited thereto. For example, each of the first to fourth emission areas EA1, EA2, EA3, and EA4, the first sensing area SA1, and the second sensing area SA2 may have a circular shape or an oval shape when viewed in the direction (the z-axis direction) perpendicular to the substrate 100 (see FIG. 7).

The display apparatus 1 (see FIG. 1) may include an array of light-emitting devices and light-receiving devices, which are arranged in the display area DA (see FIG. 1). The array of light-emitting devices and light-receiving devices may include the first to third light-emitting devices ED1, ED2, and ED3, the auxiliary light-emitting device ED4, and the first and second light-receiving devices PD1 and PD2, which are arranged two-dimensionally. According to some embodiments, the array of light-emitting devices and light-receiving devices may have a configuration in which minimal repeating units including the first to third light-emitting devices ED1, ED2, and ED3, the auxiliary light-emitting device ED4, and the first and second light-receiving devices PD1 and PD2 are repeatedly arranged in a first direction (e.g., an x direction) and a second direction (e.g., a y direction). The term “minimum repeating unit” refers to a repeating unit with the smallest number of subpixels. According to some embodiments, the first to third light-emitting devices ED1, ED2, and ED3, the auxiliary light-emitting device ED4, and the first and second light-receiving devices PD1 and PD2 included in the minimum repeating units may be arranged as in the region A of FIG. 6.

In a plan view, two second light-emitting devices ED2 and one third light-emitting device ED3 may be alternately arranged in a first column in a first direction (e.g., a y direction). That is, one second emission area EA2, another second emission area EA2, and the third emission area EA3 may be repeatedly arranged in the first column. In this regard, one auxiliary light-emitting device ED4 may be arranged between the two second light-emitting devices ED2 with respect to the first direction (e.g., the y direction). As a result, one second light-emitting device ED2, the auxiliary light-emitting device ED4, another second light-emitting device ED2, and the third light-emitting device ED3 may be repeatedly arranged in the first column in the first direction (e.g., the y direction).

Likewise, the first light-emitting device ED1 may be repeatedly arranged in a second column in the first direction (e.g., the y direction). That is, the first emission area EA1 may be repeatedly arranged in the second column. However, the first light-receiving device PD1 or the second light-receiving device PD2 may be arranged between the first light-emitting devices ED1 arranged adjacent to each other with respect to the first direction (e.g., the y direction). In this regard, the first light-receiving device PD1 and the second light-receiving device PD2 may be arranged alternately. As a result, one first light-emitting device ED1, the second light-receiving device PD2, another first light-emitting device ED1, and the first light-receiving device PD1 may be repeatedly arranged in the second column in the first direction (e.g., the y direction).

Next, one second light-emitting device ED2, the auxiliary light-emitting device ED4, another second light-emitting device ED2, and the third light-emitting device ED3 may be repeatedly arranged in a third column in the first direction (e.g., the y direction), like in the first column. However, the third column may be arranged alternately with the first column with respect to the first direction (e.g., the y direction). That is, with respect to a specific row in a second direction (e.g., an x direction), the auxiliary light-emitting device ED4 of the first column and the third light-emitting device ED3 of the third column may be arranged in the same row.

Next, one first light-emitting device ED1, the second light-receiving device PD2, another first light-emitting device ED1, and the first light-receiving device PD1 may be repeatedly arranged in a fourth column in the first direction (e.g., the y direction), like in the second column. However, the fourth column may be arranged alternately with the second column with respect to the first direction (e.g., the y direction). That is, with respect to a specific row in the second direction (e.g., the x direction), the second light-receiving device PD2 of the second column and the first light-receiving device PD1 of the fourth column may be arranged in the same row.

The first to fourth columns included in the region A of FIG. 6 are arbitrarily determined columns, and the first to fourth columns may be sequentially and repeatedly arranged in the second direction (e.g., the x direction).

FIG. 7 is a schematic cross-sectional view of a portion of the display apparatus 1 according to some embodiments. For example, FIG. 7 is a schematic cross-sectional view of a cross-section of the display apparatus 1, taken along a line II-II′ of FIG. 6.

As shown in FIG. 7, the display apparatus 1 according to some embodiments may include the substrate 100. The substrate 100 may include various materials having flexible or bendable characteristics. For example, the substrate 100 may include glass, metal, or polymer resin. Also, the substrate 100 may include polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. However, the substrate 100 may be variously modified. For example, the substrate 100 may have a multi-layer structure including two layers each including the above polymer resin and a barrier layer arranged between the two layers and including an inorganic material, such as silicon oxide, silicon nitride, or silicon oxynitride.

The first light-emitting device ED1, the second light-emitting device ED2, the third light-emitting device ED3 (see FIG. 6), the auxiliary light-emitting device ED4, the first light-receiving device PD1, the second light-receiving device PD2, the pixel circuit PC, and the sensor circuit PC′ may be located on the substrate 100. The pixel circuit PC may be electrically connected to each of the light-emitting devices and the auxiliary light-emitting device, and the sensor circuit PC′ may be electrically connected to each of the light-receiving devices.

Because the first light-emitting device ED1, the second light-emitting device ED2, the third light-emitting device ED3 (see FIG. 6), and the auxiliary light-emitting device ED4 are electrically connected to the pixel circuit PC, light emission may be controlled. Also, because the first light-receiving device PD1 and the second light-receiving device PD2 are electrically connected to the sensor circuit PC′, light detection may be controlled. The pixel circuit PC may include a plurality of thin-film transistors TFT and the storage capacitor Cst and may have substantially the same structure as the pixel circuit PC described with reference to FIG. 5. FIG. 7 shows one thin-film transistor TFT for convenience of illustration, and the thin-film transistor TFT may correspond to the first transistor T1 (see FIG. 5) described above. Likewise, the sensor circuit PC′ may include a plurality of thin-film transistors TFT′ and may have substantially the same structure as the sensor circuit PC′ described with reference to FIG. 5. FIG. 7 shows one thin-film transistor TFT′ for convenience of illustration, and the thin-film transistor TFT′ may correspond to the eighth transistor T8 (see FIG. 5) described above. Hereinafter, for convenience of description, one pixel circuit PC is mainly described.

A buffer layer 201 including an inorganic material, such as silicon oxide, silicon nitride, and/or silicon oxynitride, may be arranged between the thin-film transistor TFT and the substrate 100. The buffer layer 201 may increase the smoothness of an upper surface of the substrate 100, or may prevent or reduce penetration of impurities from the substrate 100 to a semiconductor layer Act of the thin-film transistor TFT.

As shown in FIG. 7, the thin-film transistor TFT may include the semiconductor layer Act including amorphous silicon, polysilicon, an organic semiconductor material, or an oxide semiconductor material. Also, the thin-film transistor TFT may include a gate electrode GE, a source electrode SE, and/or a drain electrode DE. The gate electrode GE may include various conductive materials and have various layered structures including, for example, a Mo layer and an Al layer. Alternatively, the gate electrode GE may include a TiNX layer, an Al layer, and/or a Ti layer. Each of the source electrode SE and the drain electrode DE may also include various conductive materials and have various layered structures including, for example, a Ti layer, an Al layer, and/or a Cu layer.

To secure insulation between the semiconductor layer Act and the gate electrode GE, a gate insulating layer 203 including an inorganic material, such as silicon oxide, silicon nitride, and/or silicon oxynitride, may be arranged between the semiconductor layer Act and the gate electrode GE. FIG. 7 shows that the gate insulating layer 203 has a shape corresponding to the entire surface of the substrate 100 and has a structure in which contact holes are formed in portions (e.g., set or predetermined portions), but embodiments according to the present disclosure are not limited thereto. For example, the gate insulating layer 203 may be patterned in the same shape as the gate electrode GE.

Also, a first interlayer insulating layer 205 including an inorganic material, such as silicon oxide, silicon nitride, and/or silicon oxynitride, may be located on the gate electrode GE. The first interlayer insulating layer 205 may have a single-layer or multi-layer structure including the above material. Such an insulating layer including an inorganic material may be formed through chemical vapor deposition (CVD) or atomic layer deposition (ALD).

The storage capacitor Cst may include a first electrode CE1 and a second electrode CE2 that overlap each other with the first interlayer insulating layer 205 therebetween. The storage capacitor Cst may overlap the thin-film transistor TFT. In this regard, FIG. 7 shows that the gate electrode GE of the thin-film transistor TFT is the first electrode CE1 of the storage capacitor Cst, but embodiments according to the present disclosure are not limited thereto. For example, the storage capacitor Cst may not overlap the thin-film transistor TFT. The second electrode CE2 of the storage capacitor Cst may include a conductive material including Mo, Al, Cu, and Ti and may have a single-layer or multi-layer structure including the above material.

A second interlayer insulating layer 207 including an inorganic material, such as silicon oxide, silicon nitride, and/or silicon oxynitride, may be located on the second electrode CE2 of the storage capacitor Cst. The second interlayer insulating layer 207 may have a single-layer or multi-layer structure including the above material.

The source electrode SE and the drain electrode DE may be located on the second interlayer insulating layer 207. Each of the source electrode SE and the drain electrode DE may include a material having excellent conductivity. Each of the source electrode SE and the drain electrode DE may include a conductive material including, for example, Mo, Al, Cu, and/or Ti and may have a single-layer or multi-layer structure including the above material. For example, each of the source electrode SE and the drain electrode DE may have a multi-layer structure of Ti/Al/Ti. However, embodiments according to the present disclosure are not limited thereto. For example, the thin-film transistor TFT may include only one of the source electrode SE and the drain electrode DE, or may not include both the source electrode SE and the drain electrode DE.

A planarization layer 208 may be arranged to cover the thin-film transistor TFT and the storage capacitor Cst. The planarization layer 208 may include an organic insulating material. For example, the planarization layer 208 may include benzocyclobutene (BCB), polyimide, hexamethyldisiloxane (HMDSO), polymethylmethacrylate (PMMA), polystyrene, a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, or a mixture thereof. According to some embodiments, a third interlayer insulating layer may be further located below the planarization layer 208. The third interlayer insulating layer may include an inorganic insulating material, such as silicon oxide, silicon nitride, or silicon oxynitride.

The first pixel electrode 1210, the second pixel electrode 2210, the third pixel electrode 3210 (see FIG. 6), the fourth pixel electrode 4210, the first sensing electrode 5210, the second sensing electrode 6210, and the bank layer 215 may be located on the planarization layer 208. The bank layer 215 may be located on the planarization layer 208 to cover an edge of each of the plurality of pixel electrodes and the plurality of sensing electrodes.

Each of the first pixel electrode 1210, the second pixel electrode 2210, the third pixel electrode 3210 (see FIG. 6), the fourth pixel electrode 4210, the first sensing electrode 5210, and the second sensing electrode 6210 may be a reflective electrode. For example, each of the first pixel electrode 1210, the second pixel electrode 2210, the third pixel electrode 3210 (see FIG. 6), the fourth pixel electrode 4210, the first sensing electrode 5210, and the second sensing electrode 6210 may include a light-transmitting conductive layer including a light-transmitting conductive oxide, such as ITO, In₂O₃, or IZO, and a reflective layer including a metal, such as Al or Ag. For example, each of the first pixel electrode 1210, the second pixel electrode 2210, the third pixel electrode 3210 (see FIG. 6), the fourth pixel electrode 4210, the first sensing electrode 5210, and the second sensing electrode 6210 may have a three-layer structure of ITO/Ag/ITO.

The bank layer 215 may include a plurality of bank layer openings respectively exposing central portions of the plurality of pixel electrodes and the plurality of sensing electrodes. For example, the bank layer 215 may have the first bank layer opening LOP1 exposing a central portion of the first pixel electrode 1210, the second bank layer opening LOP2 exposing a central portion of the second pixel electrode 2210, the third bank layer opening LOP3 (see FIG. 6) exposing a central portion of the third pixel electrode 3210 (see FIG. 6), the fourth bank layer opening LOP4 exposing a central portion of the fourth pixel electrode 4210, the fifth bank layer opening LOP5 exposing a central portion of the first sensing electrode 5210, and the sixth bank layer opening LOP6 exposing a central portion of the second sensing electrode 6210. Accordingly, each of the first to fourth bank layer openings LOP1, LOP2, LOP3, and LOP4 may define an emission area, and each of the fifth bank layer opening LOP5 and the sixth bank layer opening LOP6 may define a sensing area.

Also, the bank layer 215 may increase a distance between an edge of a pixel electrode and a counter electrode 230 or a distance between an edge of a sensing electrode and the counter electrode 230, thereby preventing or reducing instances of arcs occurring at edges of the plurality of pixel electrodes and the plurality of sensing electrodes. The bank layer 215 may include an organic insulating material, such as polyimide, polyamide, acrylic resin, BCB, HMDSO, and phenolic resin, and may be formed by a method such as spin coating.

An emission layer 222-1 may be arranged in each of the first to fourth bank layer openings LOP1, LOP2, LOP3, and LOP4 arranged in the bank layer 215. For example, the emission layer 222-1 may include a first emission layer 1222 included in the first light-emitting device ED1, a second emission layer 2222 included in the second light-emitting device ED2, a third emission layer included in the third light-emitting device ED3 (see FIG. 6), and a fourth emission layer 4222 included in the auxiliary light-emitting device ED4. The emission layer 222-1 may include an organic material including a fluorescent or phosphorescent material that emits red, green, blue, or white light. For example, the first emission layer 1222 may emit green light, the second emission layer 2222 may emit blue light, the third emission layer may emit red light, and the fourth emission layer 4222 may emit blue light.

The emission layer 222-1 may be an organic emission layer including a low-molecular weight organic material or a polymer organic material. For example, the emission layer 222-1 may be an organic emission layer and may include copper phthalocyanine, tris-8-hydroxyquinoline aluminum, a poly-phenylenevinylene (PPV)-based material, or a polyfluorene-based material.

According to some embodiments, the emission layer 222-1 may include a host material and a dopant material. The dopant material may be a material that emits light of a certain color and may include a light-emitting material. The light-emitting material may include at least one of a phosphorescent dopant, a fluorescent dopant, or a quantum dot. The host material may be a main material of the emission layer 222-1 and may be a material that helps the dopant material to emit light.

An active layer 222-2 may be arranged in each of the fifth bank layer opening LOP5 and the sixth bank layer opening LOP6 arranged in the bank layer 215. The active layer 222-2 may include a first active layer 5222 included in the first light-receiving device PD1 and a second active layer 6222 included in the second light-receiving device PD2. For example, the first active layer 5222 may detect light in the visible light wavelength band, and the second active layer 6222 may detect light in the infrared wavelength band. According to some embodiments, the second active layer 6222 may detect light in a wider wavelength band than the first active layer 5222.

The active layer 222-2 may receive light from the outside to generate excitons and then may separate the generated excitons into holes and electrons. When a (+) electric potential is applied to a sensing electrode and a (−) electric potential is applied to the counter electrode 230, holes separated in the active layer 222-2 may move toward the counter electrode 230, and electrons separated in the active layer 222-2 may move toward the sensing electrode. Accordingly, a photocurrent may be formed in a direction from the sensing electrode to the counter electrode 230. When a bias is applied between the sensing electrode and the counter electrode 230, a dark current may flow in a light-receiving device. Also, when light is incident on the light-receiving device, a photocurrent may flow in the light-receiving device. According to some embodiments, the first light-receiving device PD1 and the second light-receiving device PD2 may detect the amount of light from the ratio of the photocurrent to the dark current.

The active layer 222-2 may include a p-type organic semiconductor and an n-type organic semiconductor. In this regard, the p-type organic semiconductor may serve as an electron donor, and the n-type organic semiconductor may serve as an electron acceptor. According to some embodiments, the active layer 222-2 may be a mixed layer in which a p-type organic semiconductor and an n-type organic semiconductor are mixed. In this case, the active layer 222-2 may be formed by co-depositing the p-type organic semiconductor and the n-type organic semiconductor. When the active layer 222-2 is a mixed layer, excitons may be generated within a diffusion length from a donor-acceptor interface. According to some embodiments, the active layer 222-2 may include a first layer including a p-type organic semiconductor and a second layer including an n-type organic semiconductor. The first layer including a p-type organic semiconductor and the second layer including an n-type organic semiconductor may form a PN junction. Due to photo-induced charge separation that occurs at an interface of these layers, excitons may be efficiently separated into holes and electrons.

The p-type organic semiconductor may be a compound that serves as an electron donor for supplying electrons. According to some embodiments, the p-type organic semiconductor may be an organic compound having electron-donating properties. For example, the p-type organic semiconductor may include a metal complex including, as a ligand, a triarylamine compound, a benzidine compound, a pyrazoline compound, a styrylamine compound, a hydrazone compound, a triphenylmethane compound, a carbazole compound, a polysilane compound, a thiophene compound, a phthalocyanine compound, a naphthalocyanine compound, a cyanine compound, a merocyanine compound, an oxonol compound, a polyamine compound, an indole compound, a pyrrole compound, a pyrazole compound, a polyarylene compound, a condensed aromatic carbocyclic compound (a naphthalene derivative, an anthracene derivative, a phenanthrene derivative, a tetracene derivative, a pyrene derivative, a perylene derivative, or a fluoranthene derivative), or a nitrogen-containing heterocyclic compound, but embodiments according to the present disclosure are not limited thereto.

The n-type organic semiconductor may be a compound that serves as an electron acceptor for accepting electrons. According to some embodiments, the n-type organic semiconductor may be an organic compound having electron-accepting properties. For example, the n-type organic semiconductor may include a metal complex including, as a ligand, fullerene, a fullerene derivative, a condensed aromatic carbocyclic compound (a naphthalene derivative, an anthracene derivative, a phenanthrene derivative, a tetracene derivative, a pyrene derivative, a perylene derivative, or a fluoranthene derivative), a five to seven-membered heterocyclic compound containing nitrogen atoms, oxygen atoms, or sulfur atoms (e.g., pyridine, pyrazine, pyrimidine, pyridazine, triazine, quinoline, quinoxaline, quinazoline, phthalazine, cinnoline, isoquinoline, pteridine, acridine, phenazine, phenanthroline, tetrazole, pyrazole, imidazole, thiazole, oxazole, indazole, benzimidazole, benzotriazole, benzoxazole, benzothiazole, carbazole, purine, triazolopyridazine, triazolopyrimidine, tetrazaindene, oxadiazole, imidazopyridine, pyrrolidine, pyrrolopyridine, thiadiazolopyridine, dibenzazepine, or tribenzazepine), a polyarylene compound, a fluorene compound, a cyclopentadiene compound, a silyl compound, or a nitrogen-containing heterocyclic compound, but embodiments according to the present disclosure are not limited thereto.

The counter electrode 230 may be located on the emission layer 222-1 and the active layer 222-2. The counter electrode 230 located on the emission layer 222-1 and the active layer 222-2 may be formed as a single body. The counter electrode 230 may be a light-transmitting electrode or a reflective electrode. According to some embodiments, the counter electrode 230 may be a transparent or semi-transparent electrode and may include a metal thin film including Li, Ca, LiF/Ca, LiF/Al, Al, Ag, Mg, and a compound thereof and having a small work function. Also, the counter electrode 230 may further include a transparent conductive oxide (TCO) film, such as ITO, IZO, ZnO, or In₂O₃, in addition to the metal thin film.

A first common layer 221 may be arranged between the first pixel electrode 1210 and the emission layer 222-1 and between the first sensing electrode 5210 and the active layer 222-2, and a second common layer 223 may be arranged between the emission layer 222-1 and the counter electrode 230 and between the active layer 222-2 and the counter electrode 230.

According to some embodiments, a hole transport region may be defined between a pixel electrode and the emission layer 222-1 and between a sensing electrode and the active layer 222-2, and an electron transport region may be defined between the emission layer 222-1 and the counter electrode 230 and between the active layer 222-2 and the counter electrode 230.

The hole transport region may have a single-layer structure or a multi-layer structure. For example, the first common layer 221 may be arranged in the hole transport region. According to some embodiments, the first common layer 221 may include at least one of a hole injection layer (HIL), a hole transport layer (HTL), or an electron-blocking layer (EBL).

For example, the first common layer 221 may have a single-layer structure or a multi-layer structure. When the first common layer 221 has a multi-layer structure, the first common layer 221 may include an HIL and an HTL, an HIL and an EBL, an HTL and an EBL, or an HIL, an HTL, and an EBL, which are sequentially stacked from the first pixel electrode 1210. However, embodiments according to the present disclosure are not limited thereto.

According to some embodiments, the first common layer 221 may include at least one selected from m-MTDATA, TDATA, 2-TNATA, NPB (NPD), β-NPB, TPD, Spiro-TPD, Spiro-NPB, methylated-NPB, TAPC, HMTPD, 4,4′,4-tris (N-carbazolyl) triphenylamine (TCTA), polyaniline/dodecylbenzenesulfonic acid (PANI/DBSA), polyaniline/camphor sulfonic acid (PANI/CSA), poly(3,4-ethylenedioxythiophene)/poly(4-styrenesulfonate) (PEDOT/PSS), and polyaniline/poly(4-styrenesulfonate) (PANI/PSS).

The electron transport region may have a single-layer structure or a multi-layer structure. For example, the second common layer 223 may be arranged in the electron transport region. According to some embodiments, the second common layer 223 may include at least one of an electron injection layer (EIL), an electron transport layer (ETL), or a hole-blocking layer (HBL).

For example, the second common layer 223 may have a single-layer structure or a multi-layer structure. When the second common layer 223 has a multi-layer structure, the second common layer 223 may include an ETL and an EIL, an HBL and an EIL, an HBL and an ETL, or an HBL, an ETL, and an EIL, which are sequentially stacked from the emission layer 222-1. However, embodiments according to the present disclosure are not limited thereto.

According to some embodiments, the second common layer 223 may include at least one compound selected from 2,9-dimethyl-4,7-diphenyl-1,10-phenanthroline (BCP), 4,7-diphenyl-1,10-phenanthroline (Bphen), Alq₃, BAlq, 3-(biphenyl-4-yl)-5-(4-tert-butylphenyl)-4-phenyl-4H-1,2,4-triazole (TAZ), and NTAZ. The first light-emitting device ED1 may include the first pixel electrode 1210,

the first common layer 221, the first emission layer 1222, the second common layer 223, and the counter electrode 230, which are sequentially stacked. The second light-emitting device ED2 may include the second pixel electrode 2210, the first common layer 221, the second emission layer 2222, the second common layer 223, and the counter electrode 230, which are sequentially stacked. The third light-emitting device

ED3 (see FIG. 6) may include the third pixel electrode 3210 (see FIG. 6), the first common layer 221, the third emission layer, the second common layer 223, and the counter electrode 230, which are sequentially stacked. The auxiliary light-emitting device ED4 may include the fourth pixel electrode 4210, the first common layer 221, the fourth emission layer 4222, the second common layer 223, and the counter electrode 230, which are sequentially stacked. Likewise, the first light-receiving device PD1 may include the first sensing electrode 5210, the first common layer 221, the first active layer 5222, the second common layer 223, and the counter electrode 230, which are sequentially stacked. The second light-receiving device PD2 may include the second sensing electrode 6210, the first common layer 221, the second active layer 6222, the second common layer 223, and the counter electrode 230, which are sequentially stacked.

A capping layer may be located on the plurality of light-emitting devices and the plurality of light-receiving devices having the above structures. That is, the capping layer may be located on the counter electrode 230 and may be formed as a single body over the entire surface of the substrate 100. The capping layer may prevent or reduce instances of contaminants or impurities, such as water and oxygen, entering the display apparatus 1, thereby relatively increasing the reliability of the display apparatus 1.

The capping layer may be an organic capping layer including an organic material, an inorganic capping layer including an inorganic material, or an organic-inorganic composite capping layer including an organic material and an inorganic material. The capping layer may include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. The carbocyclic compound, the heterocyclic compound, and the amine group-containing compound may optionally be substituted with substituents including O, N, S, Se, Si, F, Cl, Br, I, or any combination thereof.

The thin-film encapsulation layer TFE may be located on the plurality of light-emitting devices and the plurality of light-receiving devices. According to some embodiments, the thin-film encapsulation layer TFE may be located on the counter electrode 230. According to some embodiments, when a capping layer is located on the counter electrode 230, the thin-film encapsulation layer TFE may be located on the capping layer. The thin-film encapsulation layer TFE may include at least one inorganic encapsulation layer and at least one organic encapsulation layer. According to some embodiments, FIG. 7 shows that the thin-film encapsulation layer TFE includes a first inorganic encapsulation layer 310, an organic encapsulation layer 320, and a second inorganic encapsulation layer 330, which are sequentially stacked.

Each of the first inorganic encapsulation layer 310 and the second inorganic encapsulation layer 330 may include at least one inorganic material selected from aluminum oxide, titanium oxide, tantalum oxide, hafnium oxide, zinc oxide, silicon oxide, silicon nitride, and silicon oxynitride. The organic encapsulation layer 320 may include a polymer-based material. The polymer-based material may include acrylic resin, epoxy-based resin, polyimide, and polyethylene. According to some embodiments, the organic encapsulation layer 320 may include acrylate. The organic encapsulation layer 320 may be formed by curing a monomer or applying a polymer. The organic encapsulation layer 320 may have transparency.

The input-sensing layer TU may be located on the thin-film encapsulation layer TFE. The input-sensing layer TU may obtain an external input, for example, coordinate information according to a touch event. As described with reference to FIG. 3, the input-sensing layer TU may include a plurality of touch electrodes and a touch insulating layer.

The color filter member CU may be located on the input-sensing layer TU. The color filter member CU may include the light-blocking layer BM, the wavelength conversion pattern 400, the color filter layer CF, a transparent organic film layer 600, and an overcoat layer OC.

The light-blocking layer BM may be located on the input-sensing layer TU. The light-blocking layer BM may include a light-blocking material and thus may at least partially absorb internally reflected light. The light-blocking material may include carbon black, carbon nanotubes, resin or paste containing black dye, and metal particles. The metal particles may include, for example, nickel (Ni), Al, Mo, and/or an alloy thereof. Also, the light-blocking material may include metal oxide particles, such as chromium oxide, or metal nitride particles, such as chromium nitride. Because the light-blocking layer BM includes a light-blocking material, the light-blocking layer BM may reduce external light reflection. According to some embodiments, the light-blocking layer BM may include the same material as that of the bank layer 215 located therebelow. However, embodiments according to the present disclosure are not limited thereto, and the light-blocking layer BM may include a material different from that of the bank layer 215.

The light-blocking layer BM may include a plurality of light-blocking layer openings corresponding to the plurality of light-emitting devices and the plurality of light-receiving devices. For example, the light-blocking layer BM may include a first light-blocking layer opening UOP1 corresponding to the first light-emitting device ED1, a second light-blocking layer opening UOP2 corresponding to the second light-emitting device ED2, a third light-blocking layer opening corresponding to the third light-emitting device ED3 (see FIG. 6), and a fourth light-blocking layer opening UOP4 corresponding to the auxiliary light-emitting device ED4. Also, the light-blocking layer BM may include a fifth light-blocking layer opening UOP5 corresponding to the first light-receiving device PD1 and a sixth light-blocking layer opening UOP6 corresponding to the second light-receiving device PD2. Accordingly, the plurality of light-blocking layer openings may respectively overlap corresponding ones of the plurality of bank layer openings. According to some embodiments, in a plan view, the area of a light-blocking layer opening may be greater than the area of a bank layer opening. For example, in a plan view, the area of the first light-blocking layer opening UOP1 may be greater than the area of the first bank layer opening LOP1. According to some embodiments, in a plan view, the shape of a light-blocking layer opening may be the same as the shape of a bank layer opening. Because the light-blocking layer BM includes the plurality of light-blocking layer openings, the light-blocking layer BM may have a lattice shape or a mesh shape.

The wavelength conversion pattern 400 and the color filter layer CF may be located on the light-blocking layer BM. According to some embodiments, the wavelength conversion pattern 400 may be arranged in a light-blocking layer opening corresponding to the auxiliary light-emitting device ED4, among the plurality of light-blocking layer openings of the light-blocking layer BM. That is, the wavelength conversion pattern 400 may be arranged in the fourth light-blocking layer opening UOP4 of the light-blocking layer BM.

The wavelength conversion pattern 400 may include an infrared quantum dot material 420 that converts light in the visible light wavelength band into light in the infrared wavelength band. The infrared quantum dot material 420 may convert blue light provided from the auxiliary light-emitting device ED4 into light in the infrared wavelength band. For example, the wavelength conversion pattern 400 may include an organic material 410 and the infrared quantum dot material 420 dispersed in the organic material 410. According to some embodiments, the wavelength conversion pattern 400 may further include a scatterer dispersed in the organic material 410. The organic material 410 may include polymer resin, such as acryl, BCB, or HMDSO.

The infrared quantum dot material 420 may have a central emission wavelength of about 700 nm to about 2,200 nm, for example, about 750 nm to about 1,500 nm. For example, a quantum dot included in the infrared quantum dot material 420 may include at least one of InCuSe, InCuS2/ZnS, InAs/InP/ZnSe, PbS, InAs, PbSe/Te, CdS, CdTe, InP, ZnSe, or ZnS. The quantum dot included in the infrared quantum dot material 420 may have a size of several nanometers, and the wavelength of light after conversion may vary depending on the size of the quantum dot. According to some embodiments, a core of the quantum dot may be selected from a Group II-VI compound, a Group III-V compound, a Group IV-VI compound, a Group IV element, a Group IV compound, and a combination thereof.

The Group II-VI compound may be selected from: a binary compound selected from CdSe, CdTe, ZnS, ZnSe, ZnTe, ZnO, HgS, HgSe, HgTe, MgSe, MgS, and a mixture thereof; a ternary compound selected from AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound selected from HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The Group III-V compound may be selected from: a binary compound selected from GaN, GaP, GaAs, GaSb, AlN, AlP, AlAs, AlSb, InN, InP, InAs, InSb, and a mixture thereof; a ternary compound selected from GaNP, GaNAs, GaNSb, GaPAS, GaPSb, AlNP, AlNAs, AlNSb, AlPAs, AlPSb, InGaP, InNP, InNAs, InNSb, InPAs, InPSb, and a mixture thereof; and a quaternary compound selected from GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. The Group IV-VI compound may be selected from: a binary compound

selected from SnS, SnSe, SnTe, PbS, PbSe, PbTe, and a mixture thereof; a ternary compound selected from SnSeS, SnSeTe, SnSTe, PbSeS, PbSeTe, PbSTe, SnPbS, SnPbSe, SnPbTe, and a mixture thereof; and a quaternary compound selected from SnPbSSe, SnPbSeTe, SnPbSTe, and a mixture thereof. The Group IV element may be selected from Si, Ge, and a mixture thereof. The Group IV compound may be a binary compound selected from SiC, SiGe, and a mixture thereof.

In this regard, the binary compound, the ternary compound, or the quaternary compound may be present in a particle with a uniform concentration, or may be present in the same particle with partially different concentration distributions. Also, the quantum dot may have a core/shell structure in which one quantum dot surrounds another quantum dot. An interface between the core and the shell may have a concentration gradient in which the concentration of an element present in the shell decreases toward a center of the quantum dot.

According to some embodiments, the quantum dot may have a core-shell structure including a core including nanocrystals and a shell surrounding the core. The shell of the quantum dot may serve as a protective layer for maintaining semiconductor characteristics by preventing or reducing chemical denaturalization of the core and/or as a charging layer for imparting electrophoretic characteristics to the quantum dot. The shell may be a single layer or a multi-layer. An interface between the core and the shell may have a concentration gradient in which the concentration of an element present in the shell decreases toward a center of the quantum dot. Examples of the shell of the quantum dot may include an oxide of metal or non-metal, a semiconductor compound, or a combination thereof.

For example, the oxide of metal or non-metal may include a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO, or a ternary compound, such as MgAl₂O₄, CoFe₂O₄, NiFe₂O₄, or CoMn₂O₄, but embodiments according to the present disclosure are not limited thereto.

The semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, and AlSb, but embodiments according to the present disclosure are not limited thereto.

Also, the quantum dot may have a shape generally used in the art and is not limited. For example, the quantum dot may include spherical, pyramidal, multi-arm, or cubic nanoparticles, nanotubes, nanowires, nanofibers, and nanoplate particles.

Because the wavelength conversion pattern 400 having the above characteristics is located on the auxiliary light-emitting device ED4, light in the visible light wavelength band emitted from the auxiliary light-emitting device ED4 may be converted into light in the infrared wavelength band and emitted to the outside. For example, light in a wavelength band of about 380 nm to about 495 nm emitted from the auxiliary light-emitting device ED4 may be converted into light in a wavelength band of about 750 nm to about 1,500 nm by the infrared quantum dot material 420 included in the wavelength conversion pattern 400.

As described above, depending on the wavelength of light emitted from the display apparatus 1, the optical sensor may sense various information from an object or a user. For example, when light in the visible light wavelength band emitted from the first light-emitting device ED1 is reflected by an object and absorbed by the first light-receiving device PD1, the optical sensor may only read surface-level information of a user's fingerprint. In contrast, when light in the infrared wavelength band that is emitted from the auxiliary light-emitting device ED4 and passes through the wavelength conversion pattern 400 is reflected by an object and absorbed by the second light-receiving device PD2, the optical sensor may even read information within a user's blood vessels. That is, in the display apparatus 1 according to some embodiments, by arranging the auxiliary light-emitting device ED4, the wavelength conversion pattern 400, and the second light-receiving device PD2, even biometric information and touch information may be sensed, in addition to fingerprint sensing.

The color filter layer CF may include a first color filter CF1 corresponding to the first light-emitting device ED1, a second color filter CF2 corresponding to the second light-emitting device ED2, and a third color filter corresponding to the third light-emitting device ED3 (see FIG. 6). The color filter layer CF may transmit only light having a wavelength within a specific band. The first color filter CF1 may be arranged in the first light-blocking layer opening UOP1, the second color filter CF2 may be arranged in the second light-blocking layer opening UOP2, and the third color filter may be arranged in the third light-blocking layer opening.

In the display apparatus 1, the color filter layer CF may be located on each pixel to reduce external light reflection. For example, a red color filter that transmits only red light may be located on a pixel that emits red light, and a blue color filter that transmits only blue light may be located on a pixel that emits blue light. Accordingly, when external light, which is white light, is incident on, for example, the red color filter, blue light and green light may be absorbed by the red color filter, and only red light may pass through the red color filter and then be reflected by a pixel electrode and emitted to the outside through the red color filter. Accordingly, when the display apparatus 1 has the color filter layer CF, external light reflection may be reduced to approximately ⅓ compared to when the color filter layer CF is not provided.

The first color filter CF1 may transmit light emitted from the first light-emitting device ED1. For example, when the first light-emitting device ED1 emits green light, the first color filter CF1 may be a green color filter that transmits green light. The second color filter CF2 may transmit light emitted from the second light-emitting device ED2. For example, when the second light-emitting device ED2 emits blue light, the second color filter CF2 may be a blue color filter that transmits blue light. The third color filter may transmit light emitted from the third light-emitting device ED3 (see FIG. 6). For example, when the third light-emitting device ED3 emits red light, the third color filter may be a red color filter that transmits red light.

The color filter layer CF may further include an auxiliary color filter ACF corresponding to the auxiliary light-emitting device ED4. According to some embodiments, the auxiliary color filter ACF may be located on the auxiliary light-emitting device ED4 and on the wavelength conversion pattern 400. Because light emitted from the auxiliary light-emitting device ED4 passes through the wavelength conversion pattern 400 and is converted into the infrared wavelength band, the auxiliary color filter ACF needs to transmit light in the infrared wavelength band. Accordingly, according to some embodiments, the auxiliary color filter ACF may include the same material as that of the third color filter that transmits red light. In this regard, the third color filter and the auxiliary color filter ACF may transmit not only light in the red wavelength band, but also light in the infrared wavelength band.

The auxiliary color filter ACF may be located on the wavelength conversion pattern 400 to prevent or reduce photodegradation due to external light. Also, because the wavelength conversion pattern 400 may convert blue light into light in the infrared wavelength band, the wavelength conversion pattern 400 may convert not only light emitted from the auxiliary light-emitting device ED4, but also blue light included in external light into light in the infrared wavelength band. Accordingly, when the auxiliary color filter ACF is not located on the wavelength conversion pattern 400, the lifespan of the infrared quantum dot material 420 may be shortened. Accordingly, in the display apparatus 1 according to some embodiments, by arranging the auxiliary color filter ACF on the auxiliary light-emitting device ED4, the lifespan efficiency of the wavelength conversion pattern 400 may be relatively improved, and external light reflection may also be reduced.

Also, the color filter layer CF may further include a first sensing color filter CF5 corresponding to the first light-receiving device PD1. The first sensing color filter CF5 may be arranged in the fifth light-blocking layer opening UOP5. Because the first light-receiving device PD1 absorbs light in the visible light wavelength band, the first sensing color filter CF5 may include the same material as that of one of the first color filter CF1, the second color filter CF2, and the third color filter. For example, when the first light-receiving device PD1 detects green light, the first sensing color filter CF5 may include the same material as that of the first color filter CF1. That is, the first sensing color filter CF5 may be a green color filter and may transmit light in a wavelength band of about 495 nm to about 580 nm.

The color filter layer CF may not be located on the second light-receiving device PD2. According to some embodiments, the transparent organic film layer 600 may be arranged in the sixth light-blocking layer opening UOP6. The transparent organic film layer 600 may be a colorless light-transmitting layer and may include an organic material, such as polyimide or HMDSO. According to some embodiments, the transparent organic film layer 600 may include the same material as that of the overcoat layer OC to be described below. However, embodiments according to the present disclosure are not limited thereto, and the transparent organic film layer 600 may include a material different from that of the overcoat layer OC.

The color filter member CU may further include the overcoat layer OC. The overcoat layer OC may be arranged to cover the wavelength conversion pattern 400, the color filter layer CF, and the transparent organic film layer 600. The overcoat layer OC may be formed as a single body over the entire surface of the substrate 100. The overcoat layer OC may be a colorless light-transmitting layer that does not have a color in the visible light band and may planarize an upper surface of the color filter member CU including the color filter layer CF. For example, the overcoat layer OC may include an organic material, such as acryl, BCB, or HMDSO.

The cover window CW may be located on the color filter member CU. The cover window CW may include at least one of glass, sapphire, or plastic. The cover window CW may be, for example, ultra-thin glass (UTG) or colorless polyimide (CPI).

The adhesive member AD may be arranged between the cover window CW and the color filter member CU. Accordingly, the adhesive member AD may couple the cover window CW and the color filter member CU to each other. As the adhesive member AD, a general adhesive member known in the art may be employed without limitation. For example, the adhesive member AD may be an OCA or a pressure sensitive adhesive (PSA).

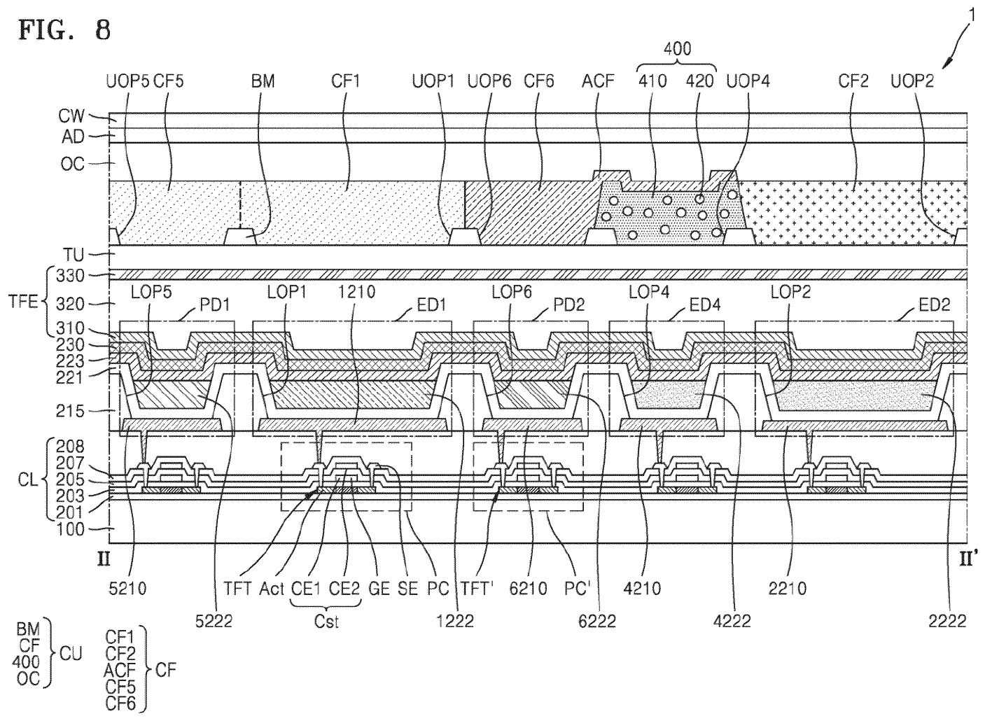

FIG. 8 is a schematic cross-sectional view of a portion of the display apparatus 1 according to some embodiments. Referring to FIG. 8, except for features regarding a second sensing color filter CF6, other features are the same as those described with reference to FIGS. 6 and 7. The same reference numerals of the elements of FIG. 8 are replaced with those of the elements described above with reference to FIGS. 6 and 7, and differences are mainly described below.

Referring to FIG. 8, the color filter member CU may include the light-blocking layer BM, the wavelength conversion pattern 400, the color filter layer CF, and the overcoat layer OC. The light-blocking layer BM may include a plurality of light-blocking layer openings corresponding to the plurality of light-emitting devices and the plurality of light-receiving devices. The wavelength conversion pattern 400 may be arranged in a light-blocking layer opening corresponding to the auxiliary light-emitting device ED4, among the plurality of light-blocking layer openings of the light-blocking layer BM. That is, the wavelength conversion pattern 400 may be arranged in the fourth light-blocking layer opening UOP4 of the light-blocking layer BM.

The color filter layer CF may include the first color filter CF1 corresponding to the first light-emitting device ED1, the second color filter CF2 corresponding to the second light-emitting device ED2, and the third color filter corresponding to the third light-emitting device ED3 (see FIG. 6). The color filter layer CF may transmit only light having a wavelength within a specific band. The first color filter CF1 may be arranged in the first light-blocking layer opening UOP1, the second color filter CF2 may be arranged in the second light-blocking layer opening UOP2, and the third color filter may be arranged in the third light-blocking layer opening.

The color filter layer CF may further include the auxiliary color filter ACF corresponding to the auxiliary light-emitting device ED4. According to some embodiments, the auxiliary color filter ACF may be located on the auxiliary light-emitting device ED4 and on the wavelength conversion pattern 400. According to some embodiments, the auxiliary color filter ACF may include the same material as that of the third color filter that transmits red light. In this regard, the third color filter and the auxiliary color filter ACF may transmit not only light in the red wavelength band, but also light in the infrared wavelength band.

Also, the color filter layer CF may include the first sensing color filter CF5 corresponding to the first light-receiving device PD1 and the second sensing color filter CF6 corresponding to the second light-receiving device PD2. The first sensing color filter CF5 may be arranged in the fifth light-blocking layer opening UOP5, and the second sensing color filter CF6 may be arranged in the sixth light-blocking layer opening UOP6. Because the first light-receiving device PD1 absorbs light in the visible light wavelength band, the first sensing color filter CF5 may include the same material as that of one of the first color filter CF1, the second color filter CF2, and the third color filter. For example, when the first light-receiving device PD1 detects green light, the first sensing color filter CF5 may include the same material as that of the first color filter CF1.

Because the second light-receiving device PD2 absorbs light in the infrared wavelength band, the second sensing color filter CF6 needs to transmit light in the infrared wavelength band. Accordingly, the second sensing color filter CF6 may include the same material as that of the third color filter that transmits red light. In this regard, the third color filter and the second sensing color filter CF6 may transmit not only light in the red wavelength band, but also light in the infrared wavelength band. According to the above structure, the second sensing color filter CF6 and the auxiliary color filter ACF may include the same material. Accordingly, the second sensing color filter CF6 and the auxiliary color filter ACF may be formed as a single body.

As a result, in the display apparatus 1 according to some embodiments, by arranging the second sensing color filter CF6 on the second light-receiving device PD2, external light reflection may be reduced more efficiently. Also, light that is emitted from the auxiliary light-emitting device ED4 and converted into infrared light through the wavelength conversion pattern 400 may be reflected by an object and then absorbed by the second light-receiving device PD2. Accordingly, in the display apparatus 1 according to some embodiments, even biometric information and touch information may be sensed, in addition to fingerprint sensing.

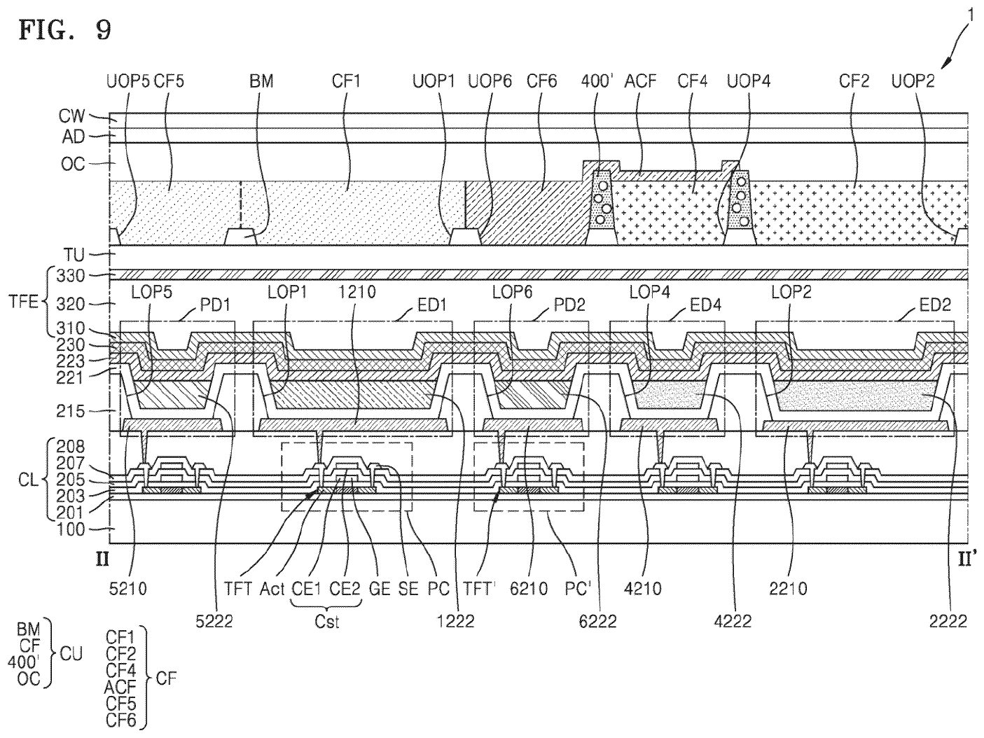

FIG. 9 is a schematic cross-sectional view of a portion of the display apparatus 1 according to some embodiments. Referring to FIG. 9, except for features regarding a wavelength conversion pattern 400′ and a fourth color filter CF4, other features are the same as those described with reference to FIG. 8. The same reference numerals of the elements of FIG. 9 are replaced with those of the elements described above with reference to FIG. 8, and differences are mainly described below.

Referring to FIG. 9, the color filter member CU may include the light-blocking layer BM, the wavelength conversion pattern 400′, the color filter layer CF, and the overcoat layer OC. The light-blocking layer BM may include a plurality of light-blocking layer openings corresponding to the plurality of light-emitting devices and the plurality of light-receiving devices.

According to some embodiments, the wavelength conversion pattern 400′ may be located on an upper surface of the light-blocking layer BM. For example, a lower surface of the wavelength conversion pattern 400′ may be in direct contact with the upper surface of the light-blocking layer BM and may not be in direct contact with the input-sensing layer TU. Only the color filter layer CF may be arranged in the plurality of light-blocking layer openings of the light-blocking layer BM.

As shown in FIG. 9, the wavelength conversion pattern 400′ may be located on the light-blocking layer BM surrounding a light-blocking layer opening corresponding to the auxiliary light-emitting device ED4, among the plurality of light-blocking layer openings of the light-blocking layer BM. In other words, the wavelength conversion pattern 400′ may be located on the light-blocking layer BM surrounding the fourth light-blocking layer opening UOP4. According to some embodiments, the wavelength conversion pattern 400′ may be arranged on, among sides of the auxiliary light-emitting device ED4 in a plan view, only a side facing the second light-receiving device PD2 and a side facing the second light-emitting device ED2. According to some embodiments, the wavelength conversion pattern 400′ may be arranged to surround the auxiliary light-emitting device ED4 in a plan view.

The color filter layer CF may include the first color filter CF1 corresponding to the first light-emitting device ED1, the second color filter CF2 corresponding to the second light-emitting device ED2, and the third color filter corresponding to the third light-emitting device ED3 (see FIG. 6). The color filter layer CF may transmit only light having a wavelength within a specific band. The first color filter CF1 may be arranged in the first light-blocking layer opening UOP1, the second color filter CF2 may be arranged in the second light-blocking layer opening UOP2, and the third color filter may be arranged in the third light-blocking layer opening.

The color filter layer CF may further include the fourth color filter CF4 corresponding to the auxiliary light-emitting device ED4. The fourth color filter CF4 may be arranged in the fourth light-blocking layer opening UOP4, and a portion of a side of the fourth color filter CF4 may be covered by the wavelength conversion pattern 400′. Because the auxiliary light-emitting device ED4 emits blue light like the second light-emitting device ED2, the fourth color filter CF4 may include the same material as that of the second color filter CF2. That is, the fourth color filter CF4 may be a blue color filter that transmits blue light.

The auxiliary color filter ACF may be located on the fourth color filter CF4. Light in the visible light wavelength band emitted from the auxiliary light-emitting device ED4 may be converted into light in the infrared wavelength band while passing through the wavelength conversion pattern 400′. Accordingly, the auxiliary color filter ACF needs to transmit light in the infrared wavelength band. The auxiliary color filter ACF may include the same material as that of the third color filter that transmits red light. In this regard, the third color filter and the auxiliary color filter ACF may transmit not only light in the red wavelength band, but also light in the infrared wavelength band.

Also, the color filter layer CF may further include the first sensing color filter CF5 corresponding to the first light-receiving device PD1 and the second sensing color filter CF6 corresponding to the second light-receiving device PD2. The first sensing color filter CF5 may be arranged in the fifth light-blocking layer opening UOP5, and the second sensing color filter CF6 may be arranged in the sixth light-blocking layer opening UOP6. According to some embodiments, the first sensing color filter CF5 may be a green color filter identical to the first color filter CF1, and the second sensing color filter CF6 may be a red color filter identical to the third color filter. That is, the second sensing color filter CF6 and the auxiliary color filter ACF may include the same material. Accordingly, the second sensing color filter CF6 and the auxiliary color filter ACF may be formed as a single body.

As a result, in the display apparatus 1 according to some embodiments, although the wavelength conversion pattern 400′ is located only on the upper surface of the light-blocking layer BM, light in the visible light wavelength band emitted from the auxiliary light-emitting device ED4 may be efficiently emitted as light in the infrared wavelength band. For example, among blue light emitted from the auxiliary light-emitting device ED4, light directed in a lateral direction may be converted into light in the infrared wavelength band through the wavelength conversion pattern 400′. Among the blue light emitted from the auxiliary light-emitting device ED4, the remaining light directed in a vertical direction may be absorbed by the auxiliary color filter ACF and thus may not be emitted to the outside. Accordingly, in the display apparatus 1 according to some embodiments, light that is emitted from the auxiliary light-emitting device ED4 and converted into the infrared wavelength band through the wavelength conversion pattern 400′ may be reflected by an object and then absorbed by the second light-receiving device PD2, and thus, even biometric information and touch information may be sensed, in addition to fingerprint sensing.

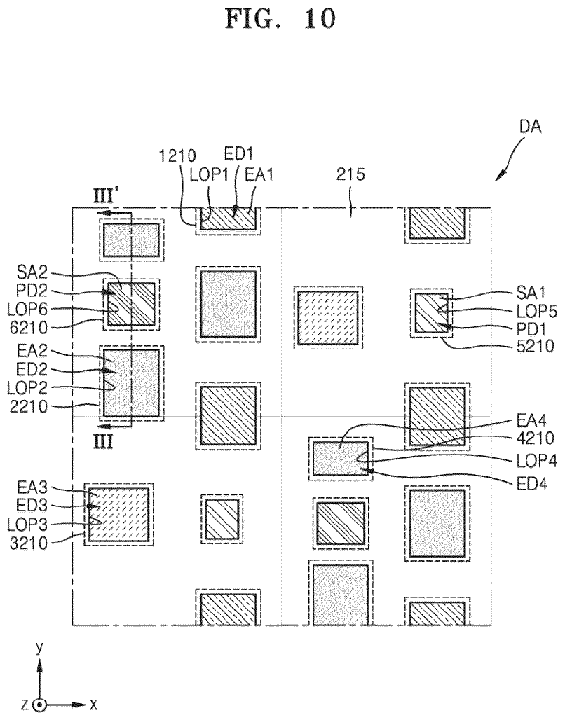

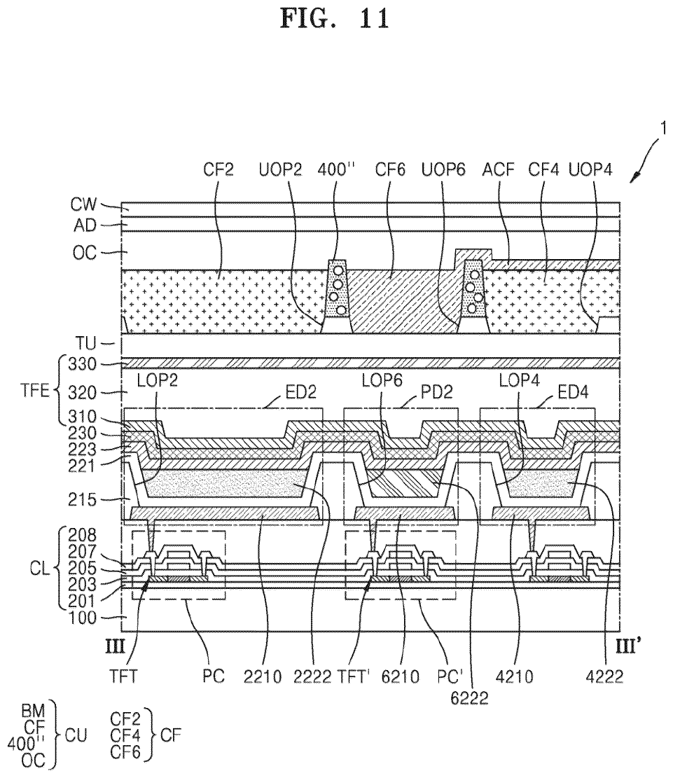

FIG. 10 is a schematic plan view of a portion of the display apparatus 1 according to some embodiments. FIG. 11 is a schematic cross-sectional view of a portion of the display apparatus 1 according to some embodiments. Referring to FIGS. 10 and 11, except for features regarding the second light-emitting device ED2, the auxiliary light-emitting device ED4, the second light-receiving device PD2, and a wavelength conversion pattern 400″, other features are the same as those described with reference to FIGS. 6 to 8. The same reference numerals of the elements of FIGS. 10 and 11 are replaced with those of the elements described above with reference to FIGS. 6 to 8, and differences are mainly described below.

Referring to FIG. 10, the display apparatus 1 (see FIG. 1) may include an array of light-emitting devices and light-receiving devices, which are arranged in the display area DA. The array of light-emitting devices and light-receiving devices may include the first to third light-emitting devices ED1, ED2, and ED3, the auxiliary light-emitting device ED4, and the first and second light-receiving devices PD1 and PD2, which are arranged two-dimensionally.

In a plan view, the auxiliary light-emitting device ED4, the second light-emitting device ED2, and the third light-emitting device ED3 may be alternately arranged in a first column in a first direction (e.g., a y direction). That is, the fourth emission area EA4, the second emission area EA2, and the third emission area EA3 may be repeatedly arranged in the first column. In this regard, one second light-receiving device PD2 may be arranged between the auxiliary light-emitting device ED4 and the second light-emitting device ED2 with respect to the first direction (e.g., the y direction). As a result, the auxiliary light-emitting device ED4, the second light-receiving device PD2, the second light-emitting device ED2, and the third light-emitting device ED3 may be repeatedly arranged in the first column in the first direction (e.g., the y direction).

Likewise, the first light-emitting device ED1 may be repeatedly arranged in a second column in the first direction (e.g., the y direction). That is, the first emission area EA1 may be repeatedly arranged in the second column. However, the second light-emitting device ED2 or the first light-receiving device PD1 may be arranged between the first light-emitting devices ED1 arranged adjacent to each other with respect to the first direction (e.g., the y direction). In this regard, the second light-emitting device ED2 and the first light-receiving device PD1 may be arranged alternately. As a result, one first light-emitting device ED1, the second light-emitting device ED2, another first light-emitting device ED1, and the first light-receiving device PD1 may be repeatedly arranged in the second column in the first direction (e.g., the y direction).

Next, the auxiliary light-emitting device ED4, the second light-receiving device PD2, the second light-emitting device ED2, and the third light-emitting device ED3 may be repeatedly arranged in a third column in the first direction (e.g., the y direction), like in the first column. However, the third column may be arranged alternately with the first column with respect to the first direction (e.g., the y direction). That is, with respect to a specific row in a second direction (e.g., an x direction), the second light-receiving device PD2 of the first column and the third light-emitting device ED3 of the third column may be arranged in the same row.

Next, one first light-emitting device ED1, the second light-emitting device ED2, another first light-emitting device ED1, and the first light-receiving device PD1 may be repeatedly arranged in a fourth column in the first direction (e.g., the y direction), like in the second column. However, the fourth column may be arranged alternately with the second column with respect to the first direction (e.g., the y direction). That is, with respect to a specific row in the second direction (e.g., the x direction), the second light-emitting device ED2 of the second column and the first light-receiving device PD1 of the fourth column may be arranged in the same row.

The first to fourth columns included in FIG. 10 are arbitrarily determined columns, and the first to fourth columns may be sequentially and repeatedly arranged in the second direction (e.g., the x direction).

As a result, referring to FIGS. 10 and 11, the second light-receiving device PD2 may be arranged between the auxiliary light-emitting device ED4 and the second light-emitting device ED2 with respect to the first direction (e.g., the y direction). In other words, the auxiliary light-emitting device ED4 may be arranged on one side of the second light-receiving device PD2, and the second light-emitting device ED2 may be arranged on the other side of the second light-receiving device PD2.

Referring to FIG. 11, the color filter member CU may include the light-blocking layer BM, the wavelength conversion pattern 400″, the color filter layer CF, and the overcoat layer OC. The light-blocking layer BM may include a plurality of light-blocking layer openings corresponding to the plurality of light-emitting devices and the plurality of light-receiving devices.

According to some embodiments, the wavelength conversion pattern 400″ may be located on an upper surface of the light-blocking layer BM. For example, a lower surface of the wavelength conversion pattern 400″ may be in direct contact with the upper surface of the light-blocking layer BM and may not be in direct contact with the input-sensing layer TU. Only the color filter layer CF may be arranged in the plurality of light-blocking layer openings of the light-blocking layer BM.

As shown in FIG. 11, the wavelength conversion pattern 400″ may be located on the light-blocking layer BM surrounding a light-blocking layer opening corresponding to the second light-receiving device PD2, among the plurality of light-blocking layer openings of the light-blocking layer BM. In other words, the wavelength conversion pattern 400″ may be located on the light-blocking layer BM surrounding the sixth light-blocking layer opening UOP6. According to some embodiments, the wavelength conversion pattern 400″ may be arranged on, among sides of the second light-receiving device PD2 in a plan view, only a side facing the auxiliary light-emitting device ED4 and a side facing the second light-emitting device ED2. According to some embodiments, the wavelength conversion pattern 400″ may be arranged to surround the second light-receiving device PD2 in a plan view.

The color filter layer CF may include the second color filter CF2 corresponding to the second light-emitting device ED2, the fourth color filter CF4 corresponding to the auxiliary light-emitting device ED4, the auxiliary color filter ACF located on the fourth color filter CF4, and the second sensing color filter CF6 corresponding to the second light-receiving device PD2. As described above, the second color filter CF2 and the fourth color filter CF4 may be blue color filters that transmit blue light, and the auxiliary color filter ACF and the second sensing color filter CF6 may be red color filters that transmit red light. In this regard, the auxiliary color filter ACF and the second sensing color filter CF6 may also transmit light in the infrared wavelength band.

As a result, in the display apparatus 1 according to some embodiments, although the wavelength conversion pattern 400″ is located only on the upper surface of the light-blocking layer BM, light in the infrared wavelength band may be efficiently detected. For example, blue light emitted from the second light-emitting device ED2 and the auxiliary light-emitting device ED4 may be reflected by an object and then directed to the second light-receiving device PD2 arranged between the auxiliary light-emitting device ED4 and the second light-emitting device ED2. However, some of the light directed to the second light-receiving device PD2 may pass through the wavelength conversion pattern 400″ and be converted from blue light to light in the infrared wavelength band. The light converted into the infrared wavelength band through the wavelength conversion pattern 400″ may be absorbed and detected by the second light-receiving device PD2. That is, by arranging the wavelength conversion pattern 400″ on a side of the second light-receiving device PD2 in a plan view, the second light-receiving device PD2 may detect not only light emitted from the auxiliary light-emitting device ED4, but also light emitted from the second light-emitting device ED2. Accordingly, in the display apparatus 1 according to some embodiments, because the amount of light that may be detected increases, various sensing information may be detected, and sensing sensitivity may be relatively improved.

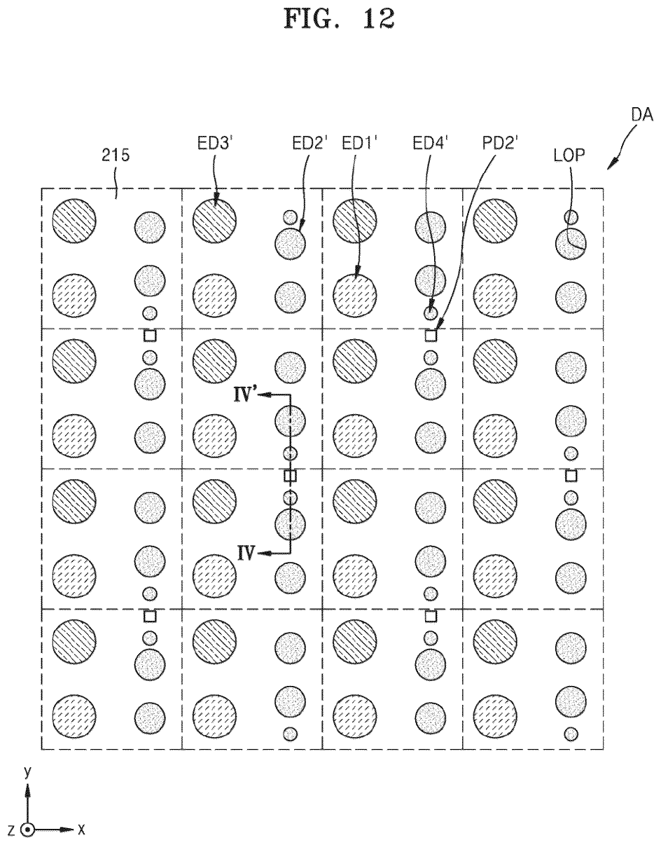

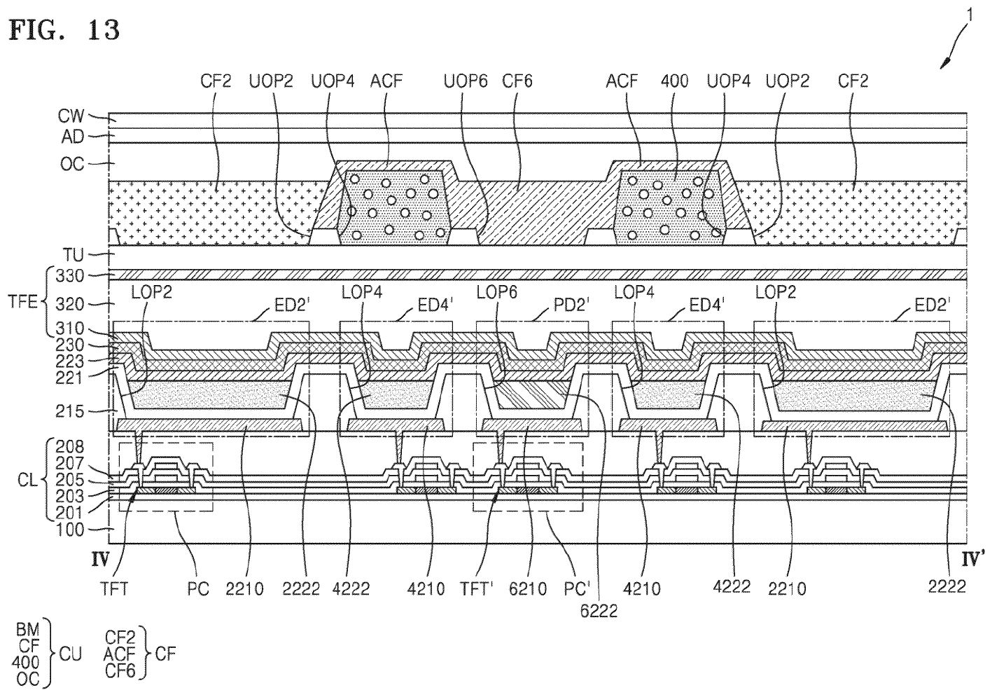

FIG. 12 is a schematic plan view of a portion of the display apparatus 1 according to some embodiments. FIG. 13 is a schematic cross-sectional view of a portion of the display apparatus 1 according to some embodiments. Referring to FIGS. 12 and 13, except for the shape and arrangement of the plurality of light-emitting devices and the plurality of light-receiving devices in a plan view, other features are the same as those described with reference to FIGS. 6 to 8. The same reference numerals of the elements of FIGS. 12 and 13 are replaced with those of the elements described above with reference to FIGS. 6 to 8, and differences are mainly described below.

Referring to FIG. 12, the display apparatus 1 (see FIG. 1) may include an array of light-emitting devices and light-receiving devices, which are arranged in the display area DA. The array of light-emitting devices and light-receiving devices may include first to third light-emitting devices ED1′, ED2′, and ED3′, an auxiliary light-emitting device ED4′, and first second light-receiving device PD2′, which are arranged two-dimensionally.

In a plan view, the first light-emitting device ED1′ and the third light-emitting device ED3′ may be alternately arranged in a first column in a first direction (e.g., a y direction). Also, second light-emitting devices ED2′ may be repeatedly arranged in a second column that is parallel to the first column in the first direction (e.g., the y direction). That is, as shown in FIG. 12, one first light-emitting device ED1′, two second light-emitting devices ED2′, and one third light-emitting device ED3′ may be arranged in one virtual quadrangular area.

In this regard, two auxiliary light-emitting devices ED4′ and one second light-receiving device PD2′ may be arranged between the second light-emitting devices ED2′ arranged adjacent to each other, in the second column in the first direction (e.g., the y direction). However, the auxiliary light-emitting device ED4′ and the second light-receiving device PD2′ may not be arranged in all spaces between each pair of second light-emitting devices ED2′ and may be arranged only in some of such spaces. For example, as shown in FIG. 12, two auxiliary light-emitting devices ED4′ and one second light-receiving device PD2′ may be arranged in two virtual quadrangular areas.

As a result, two second light-emitting devices ED2′, one auxiliary light-emitting device ED4′, one second light-receiving device PD2′, one auxiliary light-emitting device ED4′, and two second light-emitting devices ED2′ may be repeatedly arranged in the second column in the first direction (e.g., the y direction). In other words, the second light-receiving device PD2′ may be arranged between the auxiliary light-emitting devices ED4′ adjacent to each other and between the second light-emitting devices ED2′ adjacent to each other.

In a plan view, the first light-emitting device ED1′ and the third light-emitting device ED3′ may be alternately arranged in a third column in the first direction (e.g., the y direction). That is, the third column may be arranged parallel to the first column.

Next, two second light-emitting devices ED2′, one auxiliary light-emitting device ED4′, one second light-receiving device PD2′, one auxiliary light-emitting device ED4′, and two second light-emitting devices ED2′ may be repeatedly arranged in a fourth column in the first direction (e.g., the y direction), like in the second column. However, the fourth column may be arranged alternately with the second column with respect to the first direction (e.g., the y direction). For example, with respect to a second direction (e.g., an x direction), the second light-receiving device PD2′ of the second column may be arranged in a different row from the second light-receiving device PD2′ of the fourth column.

The bank layer 215 may include a plurality of bank layer openings LOP corresponding to the plurality of light-emitting devices and the plurality of light-receiving devices. As shown in FIG. 12, each of the plurality of bank layer openings LOP may have a circular shape or an oval shape. However, embodiments according to the present disclosure are not limited thereto, and each of the plurality of bank layer openings LOP may have a polygonal shape.

Next, referring to FIG. 13, the color filter member CU may include the light-blocking layer BM, the wavelength conversion pattern 400, the color filter layer CF, and the overcoat layer OC. The light-blocking layer BM may include a plurality of light-blocking layer openings corresponding to the plurality of light-emitting devices and the plurality of light-receiving devices. The wavelength conversion pattern 400 may be arranged in a light-blocking layer opening corresponding to the auxiliary light-emitting device ED4′, among the plurality of light-blocking layer openings of the light-blocking layer BM. That is, the wavelength conversion pattern 400 may be arranged in the fourth light-blocking layer opening UOP4 of the light-blocking layer BM.

The color filter layer CF may include the second color filter CF2 corresponding to the second light-emitting device ED2′, the auxiliary color filter ACF corresponding to the auxiliary light-emitting device ED4′, and the second sensing color filter CF6 corresponding to the second light-receiving device PD2′. The second color filter CF2 may be arranged in the second light-blocking layer opening UOP2, the auxiliary color filter ACF may be located on the wavelength conversion pattern 400, and the second sensing color filter CF6 may be arranged in the sixth light-blocking layer opening UOP6. As described above, the second color filter CF2 may be a blue color filter that transmits blue light, and the auxiliary color filter ACF and the second sensing color filter CF6 may be red color filters that transmit red light. Accordingly, the auxiliary color filter ACF and the second sensing color filter CF6 may be formed as a single body.

Accordingly, in the display apparatus 1 according to some embodiments, light in the infrared wavelength band may be efficiently detected. For example, blue light emitted from the auxiliary light-emitting device ED4′ may pass through the wavelength conversion pattern 400 located thereon, be converted into light in the infrared wavelength band, and then be reflected by an object and absorbed by the second light-receiving device PD2. In this regard, because the auxiliary light-emitting device ED4′ is arranged on both sides of the second light-receiving device PD2, the absolute amount of light that may be detected may increase, thereby relatively improving the sensing sensitivity of the optical sensor. Also, the wavelength conversion pattern 400 and the auxiliary color filter ACF may be formed to suit an emission angle of the second light-emitting device ED2′ and thus may not affect the luminescence efficiency of the second light-emitting device ED2′. As a result, in the display apparatus 1 according to some embodiments, while maintaining excellent image quality, various information, such as fingerprints and biometric information, may be sensed, and sensing sensitivity may be relatively improved.

In a display apparatus according to some embodiments as described above, a light-receiving device may absorb light in a wider wavelength band (e.g., a relatively wider wavelength band), and thus, various sensing may be performed, and sensing sensitivity may be relatively improved. However, the above characteristics are only examples, and the scope of embodiments according to the present disclosure are not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

what is claimed is:

1. A display apparatus comprising:
a substrate;
a light-emitting device on the substrate and including a first light-emitting device, a second light-emitting device, and a third light-emitting device, the first to third light-emitting devices being configured to emit light of different colors from each other;
an auxiliary light-emitting device on the substrate and spaced apart from the light-emitting device;
a light-receiving device on the substrate and including a first light-receiving device and a second light-receiving device, the first light-receiving device being configured to absorb light in a visible light wavelength band, and the second light-receiving device being configured to absorb light in an infrared wavelength band;
a thin-film encapsulation layer on the light-emitting device, the auxiliary light-emitting device, and the light-receiving device;
a light-blocking layer on the thin-film encapsulation layer and including a plurality of openings respectively corresponding to the light-emitting device, the auxiliary light-emitting device, and the light-receiving device; and
a wavelength conversion pattern on the light-blocking layer,
wherein the wavelength conversion pattern includes an infrared quantum dot material configured to convert light in the visible light wavelength band into light in the infrared wavelength band.

2. The display apparatus of claim 1, wherein an emission layer included in the auxiliary light-emitting device is configured to emit light of a same color as that of light emitted from one of the first light-emitting device, the second light-emitting device, and the third light-emitting device.

3. The display apparatus of claim 2, wherein the first light-emitting device is further configured to emit light in a wavelength band in a range of 495 nanometers (nm) to 580 nm,
the second light-emitting device is further configured to emit light in a wavelength band in a range of 380 nm to 495 nm, and
the third light-emitting device is further configured to emit light in a wavelength band in a range of 580 nm to 780 nm.

4. The display apparatus of claim 3, wherein the emission layer included in the auxiliary light-emitting device is further configured to emit light in a wavelength band in a range of 380 nm to 495 nm.

5. The display apparatus of claim 1, wherein the first light-receiving device is further configured to absorb light in a wavelength band in a range of 380 nm to 780 nm, and
the second light-receiving device is further configured to absorb light in a wavelength band in a range of 750 nm to 1,500 nm.

6. The display apparatus of claim 1, wherein, in a plan view, an emission area of the auxiliary light-emitting device is smaller than an emission area of each of the first light-emitting device, the second light-emitting device, and the third light-emitting device.

7. The display apparatus of claim 1, wherein the auxiliary light-emitting device and the second light-receiving device are arranged adjacent to each other.

8. The display apparatus of claim 7, wherein, in a plan view, the auxiliary light-emitting device is arranged between two second light-emitting devices arranged adjacent to each other.

9. The display apparatus of claim 7, wherein, in a plan view, the second light-receiving device is arranged between the second light-emitting device and the auxiliary light-emitting device.

10. The display apparatus of claim 7, wherein, in a plan view, the second light-receiving device is arranged between two auxiliary light-emitting devices arranged adjacent to each other.

11. The display apparatus of claim 1, further comprising a color filter layer on the light-blocking layer and the wavelength conversion pattern,
wherein the color filter layer includes a first color filter corresponding to the first light-emitting device, a second color filter corresponding to the second light-emitting device, and a third color filter corresponding to the third light-emitting device.

12. The display apparatus of claim 11, further comprising a transparent organic film layer in an opening corresponding to the second light-receiving device, among the plurality of openings of the light-blocking layer.

13. The display apparatus of claim 11, further comprising:
a first sensing color filter in an opening corresponding to the first light-receiving device, among the plurality of openings of the light-blocking layer; and
a second sensing color filter in an opening corresponding to the second light-receiving device, among the plurality of openings of the light-blocking layer.

14. The display apparatus of claim 13, wherein the first sensing color filter includes a same material as that of the first color filter corresponding to the first light-emitting device, the first light-emitting device being further configured to emit green light.

15. The display apparatus of claim 13, wherein the second sensing color filter includes a same material as that of the third color filter corresponding to the third light-emitting device, the third light-emitting device being further configured to emit red light.

16. The display apparatus of claim 11, wherein the wavelength conversion pattern is in an opening corresponding to the auxiliary light-emitting device, among the plurality of openings of the light-blocking layer.

17. The display apparatus of claim 16, further comprising an auxiliary color filter on the wavelength conversion pattern,
wherein the auxiliary color filter includes a same material as that of the third color filter corresponding to the third light-emitting device, the third light-emitting device being further configured to emit red light.

18. The display apparatus of claim 11, wherein the wavelength conversion pattern is on an upper surface of the light-blocking layer.

19. The display apparatus of claim 18, further comprising a fourth color filter in an opening corresponding to the auxiliary light-emitting device, among the plurality of openings of the light-blocking layer,
wherein the fourth color filter includes a same material as that of the second color filter corresponding to the second light-emitting device, the second light-emitting device being further configured to emit blue light.

20. The display apparatus of claim 19, further comprising an auxiliary color filter on the fourth color filter,
wherein the auxiliary color filter includes a same material as that of the third color filter corresponding to the third light-emitting device, the third light-emitting device being further configured to emit red light.

21. The display apparatus of claim 18, wherein the wavelength conversion pattern is on the light-blocking layer surrounding an opening corresponding to the auxiliary light-emitting device, among the plurality of openings of the light-blocking layer.

22. The display apparatus of claim 18, wherein the wavelength conversion pattern is on the light-blocking layer surrounding an opening corresponding to the second light-receiving device, among the plurality of openings of the light-blocking layer.
